(19) United States
(12) Patent Application Publication
(10) Pub. No.: US 2024/0347572 A1
(43) Pub. Date: Oct. 17, 2024

(54) PHOTODETECTOR AND ELECTRONIC APPARATUS

(71) Applicant: SONY SEMICONDUCTOR SOLUTIONS CORPORATION, KANAGAWA (JP)

(72) Inventors: HIROSHI ISOBE, KANAGAWA (JP); TAICHI YAMADA, KANAGAWA (JP); YOICHI NEGORO, KANAGAWA (JP); ATSUSHI TODA, KANAGAWA (JP)

(21) Appl. No.: 18/682,296

(22) PCT Filed: Mar. 24, 2022
(86) PCT No.: PCT/JP2022/013959

§ 371 Date: Feb. 8, 2024

(30) Foreign Application Priority Data
Aug. 24, 2021 (JP) 2021-136266

(51) Int. Cl. H01L 27/146

(52) U.S. Cl. CPC H01L 27/14634; H01L 27/14636; H01L 27/1469

(57) ABSTRACT

Provided is a photodetector in which the deterioration of contact characteristics between connection pads is prevented. The photodetector includes at least two semiconductor layers, and a wiring layer on one side in a stacking direction and a wiring layer on another side in the stacking direction, the wiring layers being interposed between the semiconductor layers, each including an insulating film and a connection pad provided in the insulating film, and being electrically coupled to each other with surfaces of the connection pads bonded together, in which the at least two semiconductor layers include a semiconductor layer with a photoelectric conversion region on a light incident surface side, the insulating film includes a first insulating film and a second insulating film that includes a material with a higher rigidity than a material of the first insulating film and penetrates the first insulating film in the stacking direction, and the second insulating film is provided between the connection pad and at least one of the semiconductor layers.

### TECHNICAL FIELD

The present technology (the technology according to the present disclosure) relates to a photodetector and an electronic apparatus, in particular, to a stacked photodetector and an electronic apparatus.

### BACKGROUND ART

In stacked image sensors, there are cases where wafers are directly bonded together by hybrid bonding. In hybrid bonding, wafers are electrically bonded together by bonding the metal-made connection pads formed in the wiring layers together (for example, PTL 1).

Further, to prevent an increase in parasitic capacitance between wiring lines, low dielectric constant insulating materials are sometimes used as the insulating films of the wiring layers (for example, PTL 2).

### CITATION LIST

### Patent Literature

[PTL 1]
Japanese Patent Laid-Open No. 2019-110260
[PTL 2]
Japanese Patent Laid-Open No. 2015-76502

### SUMMARY

### Technical Problem

Connection pads are subjected to heat treatment after being superposed on each other. Through this heat treatment, the metal that makes up the connection pads expands. This prevents the deterioration of contact characteristics between the connection pads of the pads. Besides, such connection pads have been reduced in dimensions as miniaturization progresses. As the dimensions of connection pads are reduced, the volume of the metal that makes up the connection pads is reduced. Besides, as the volume of metal is reduced, the amount of expansion due to heat treatment is reduced. Further, it is known that low dielectric constant insulating materials have a lower Young's modulus than, for example, silicon oxide.

It is an object of the present technology to provide a photodetector and an electronic apparatus in which deterioration of contact characteristics between connection pads is prevented.

### Solution to Problem

A photodetector according to an aspect of the present technology includes at least two semiconductor layers, and a wiring layer on one side in a stacking direction and a wiring layer on another side in the stacking direction, the wiring layers being interposed between the semiconductor layers, each including an insulating film and a connection pad provided in the insulating film, and being electrically coupled to each other with surfaces of the connection pads bonded together, in which the at least two semiconductor layers include a semiconductor layer with a photoelectric conversion region on a light incident surface side, the insulating film includes a first insulating film and a second insulating film that includes a material with a higher rigidity than a material of the first insulating film and penetrates the first insulating film in the stacking direction, and the second insulating film is provided between the connection pad and at least one of the semiconductor layers.

A photodetector according to another aspect of the present technology includes at least two semiconductor layers, and a wiring layer on one side in a stacking direction and a wiring layer on another side in the stacking direction, the wiring layers being interposed between the semiconductor layers, each including an insulating film and a connection pad provided in the insulating film, and being electrically coupled to each other with surfaces of the connection pads bonded together, in which the at least two semiconductor layers include a semiconductor layer with a photoelectric conversion region on a light incident surface side, and at least one of the connection pads has a first portion including a first metal and forming the surface of the at least one of the connection pads, and a second portion provided between the first portion and the insulating film and including a second metal that is more easily plastically deformed than the first metal.

A photodetector according to an aspect of the present technology includes at least two semiconductor layers, and a wiring layer on one side in a stacking direction and a wiring layer on another side in the stacking direction, the wiring layers being interposed between the semiconductor layers, each including an insulating film and a connection pad provided in the insulating film, and being electrically coupled to each other with surfaces of the connection pads bonded together, in which the at least two semiconductor layers include a semiconductor layer with a photoelectric conversion region on a light incident surface side, and a linear expansion coefficient of a material of a third portion which is a portion of the insulating film adjacent to a side surface of the connection pad is smaller than a linear expansion coefficient of a material of a fourth portion which is a portion of the insulating film adjacent to a bottom surface of the connection pad.

An electronic apparatus according to an aspect of the present technology includes the photodetector, and an optical system configured to form an image of image light from an object on the photodetector.

### BRIEF DESCRIPTION OF DRAWINGS

FIG. 1 is a chip layout diagram depicting a configuration example of a photodetector according to a first embodiment of the present technology.

FIG. 2 is a block diagram depicting a configuration example of the photodetector according to the first embodiment of the present technology.

FIG. 3 is an equivalent circuit diagram of a pixel of the photodetector according to the first embodiment of the present technology.

FIG. 4A is a longitudinal sectional view of the photodetector according to the first embodiment of the present technology.

FIG. 4B is a partial enlarged view depicting a main part of FIG. 4A in an enlarged manner.

FIG. 5A is a process sectional view depicting a method of manufacturing the photodetector according to the first embodiment of the present technology.

FIG. 5B is a process sectional view following FIG. 5A.

FIG. 5C is a process sectional view following FIG. 5B.

FIG. 5D is a process sectional view following FIG. 5C.

FIG. 5E is a process sectional view following FIG. 5D.

FIG. 5F is a process sectional view following FIG. 5E.

FIG. 5G is a process sectional view following FIG. 5F.

FIG. 5H is a process sectional view following FIG. 5G.

FIG. 5I is a process sectional view following FIG. 5H.

FIG. 5J is a process sectional view following FIG. 5I.

FIG. 5K is a process sectional view following FIG. 5J.

FIG. 5L is a process sectional view following FIG. 5K.

FIG. 5M is a process sectional view following FIG. 5L.

FIG. 5N is a process sectional view following FIG. 5M.

FIG. 6 is a partial enlarged view depicting a main part of a longitudinal section of a photodetector according to another mode of the first embodiment of the present technology in an enlarged manner.

FIG. 7 is a partial enlarged view depicting a main part of a longitudinal section of a photodetector according to a first modified example of the first embodiment of the present technology in an enlarged manner.

FIG. 8A is a process sectional view depicting a method of manufacturing the photodetector according to the first modified example of the first embodiment of the present technology.

FIG. 8B is a process sectional view following FIG. 8A.

FIG. 8C is a process sectional view following FIG. 8B.

FIG. 8D is a process sectional view following FIG. 8C.

FIG. 9 is a longitudinal sectional view of a photodetector according to a second embodiment of the present technology.

FIG. 10 is an explanatory diagram depicting a configuration of a connection pad of the photodetector according to the second embodiment of the present technology.

FIG. 11A is a process sectional view depicting a method of manufacturing the photodetector according to the second embodiment of the present technology.

FIG. 11B is a process sectional view following FIG. 11A.

FIG. 11C is a process sectional view following FIG. 11B.

FIG. 11D is a process sectional view following FIG. 11C.

FIG. 11E is a process sectional view following FIG. 11D.

FIG. 11F is a process sectional view following FIG. 11E.

FIG. 12 is an explanatory diagram depicting a configuration of a connection pad of a photodetector according to a first modified example of the second embodiment of the present technology.

FIG. 13 is an explanatory diagram depicting a configuration of a connection pad of a photodetector according to a second modified example of the second embodiment of the present technology.

FIG. 14 is a longitudinal sectional view of a photodetector according to a third embodiment of the present technology.

FIG. 15 is an explanatory diagram depicting a configuration of an insulating film around a connection pad of the photodetector according to the third embodiment of the present technology.

FIG. 16A is a process sectional view depicting a method of manufacturing the photodetector according to the third embodiment of the present technology.

FIG. 16B is a process sectional view following FIG. 16A.

FIG. 16C is a process sectional view following FIG. 16B.

FIG. 16D is a process sectional view following FIG. 16C.

FIG. 16E is a process sectional view following FIG. 16D.

FIG. 16F is a process sectional view following FIG. 16E.

FIG. 17 is an explanatory diagram depicting a configuration of a contact layer of a photodetector according to a first modified example of the third embodiment of the present technology.

FIG. 18A is a process sectional view depicting a method of manufacturing the photodetector according to the first modified example of the third embodiment of the present technology.

FIG. 18B is a process sectional view following FIG. 18A.

FIG. 18C is a process sectional view following FIG. 18B.

FIG. 18D is a process sectional view following FIG. 18C.

FIG. 18E is a process sectional view following FIG. 18D.

FIG. 18F is a process sectional view following FIG. 18E.

FIG. 18G is a process sectional view following FIG. 18F.

FIG. 19 is a diagram depicting a schematic configuration of an electronic apparatus according to a fourth embodiment of the present technology.

FIG. 20 is a block diagram depicting an example of a schematic configuration of a vehicle control system.

FIG. 21 is a diagram of assistance in explaining an example of installation positions of an outside-vehicle information detecting section and an imaging section.

FIG. 22 is a view depicting an example of a schematic configuration of an endoscopic surgery system.

FIG. 23 is a block diagram depicting an example of a functional configuration of a camera head and a camera control unit (CCU).

### DESCRIPTION OF EMBODIMENTS

Now, preferred modes for carrying out the present technology are described with reference to the drawings. Note that the embodiments described below represent examples of representative embodiments of the present technology, and the scope of the present technology should not be narrowly interpreted on the basis of these.

In the illustration of the drawings referred to below, the identical or similar portions are denoted by the identical or similar reference signs. However, it should be noted that the drawings are schematic, and hence, the relations between thickness and planar dimensions, the ratios of the thicknesses of respective layers, and the like are different from the actual ones. Thus, specific thicknesses and dimensions should be determined with reference to the following description. Further, the drawings are sometimes different from each other in dimensional relation or ratio, as a matter of course.

Further, each embodiment described below exemplifies a device or method for embodying the technical ideas of the present technology, and the technical ideas of the present technology are not specific to the following in terms of the materials, shapes, structures, arrangement, and the like of components. The technical ideas of the present technology can be modified in various ways within the technical scope defined by the claims described in CLAIMS.

Descriptions are given in the following order.
1. First Embodiment
2. Second Embodiment
3. Third Embodiment
4. Fourth Embodiment
Application Example to Electronic Apparatus
Application Example to Mobile Body
Application Example to Endoscopic Surgery System

### First Embodiment

In a first embodiment, an example of applying the present technology to a photodetector, which is a back-illuminated CMOS (Complementary Metal Oxide Semiconductor) image sensor, is described.

### <<Overall Configuration of Photodetector>>

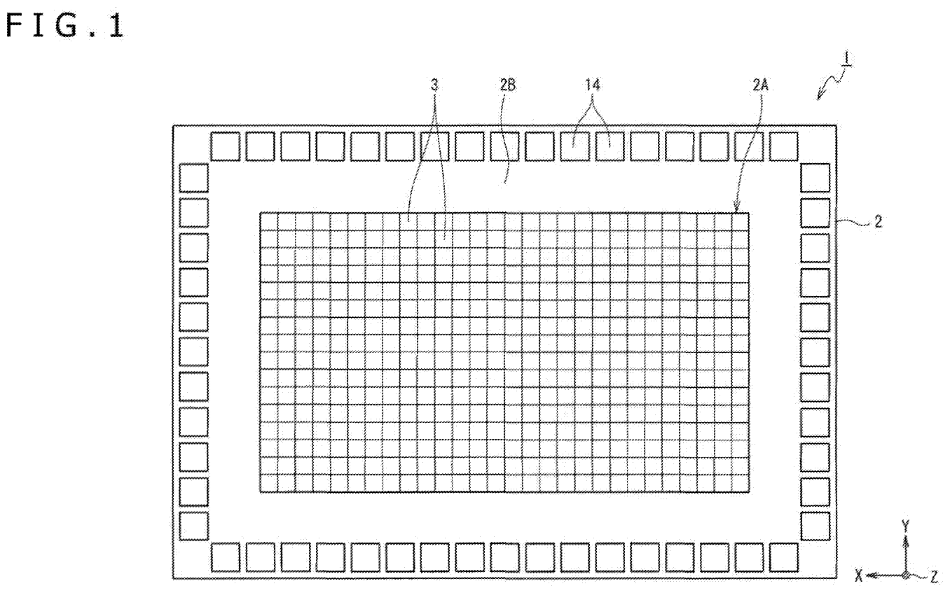

First, the overall configuration of a photodetector 1 is described. As depicted in FIG. 1, the photodetector 1 according to the first embodiment of the present technology primarily includes a semiconductor chip 2 with a rectangular two-dimensional planar shape when viewed in plan view. That is, the photodetector 1 is mounted on the semiconductor chip 2. As depicted in FIG. 19, this photodetector 1 captures image light (incident light 106) from an object through an optical system (optical lens) 102, converts the light amount of the incident light 106, an image of which has been formed on the image pickup surface, into electrical signals on a pixel-by-pixel basis, and outputs the electrical signals as pixel signals.

As depicted in FIG. 1, the semiconductor chip 2 having mounted thereon the photodetector 1 includes, in a two-dimensional plane including an X direction and a Y direction that intersect each other, a rectangular pixel region 2A provided at a central part, and a peripheral region 2B provided outside this pixel region 2A to surround the pixel region 2A.

The pixel region 2A is a light-receiving surface for receiving light condensed by the optical system 102 depicted in FIG. 19, for example. Besides, in the pixel region 2A, a plurality of pixels 3 is arranged in a matrix in the two-dimensional plane including the X direction and the Y direction. In other words, the pixels 3 are repeatedly arranged in each of the X direction and the Y direction that intersect each other in the two-dimensional plane. Note that, in the present embodiment, as an example, the X direction is orthogonal to the Y direction. Further, the direction orthogonal to both the X direction and the Y direction is a Z direction (thickness direction).

As depicted in FIG. 1, a plurality of bonding pads 14 is arranged in the peripheral region 2B. The plurality of bonding pads 14 each is arrayed along each side of the four sides in the two-dimensional plane of the semiconductor chip 2, for example. Each of the multiple bonding pads 14 is an input/output terminal used when the semiconductor chip 2 is electrically connected to an external device.

### <Logic Circuit>

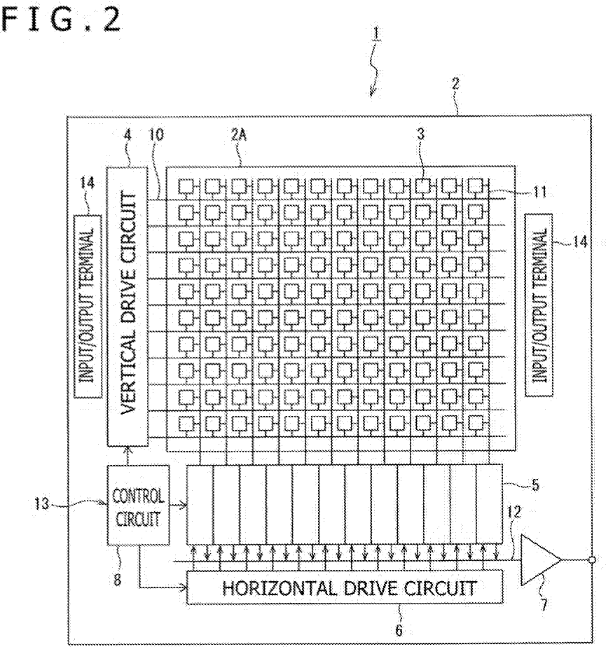

As depicted in FIG. 2, the semiconductor chip 2 includes a logic circuit 13 including a vertical drive circuit 4, column signal processing circuits 5, a horizontal drive circuit 6, an output circuit 7, a control circuit 8, and the like. The logic circuit 13 includes a CMOS (Complementary MOS) circuit including, for example, an n-channel conductivity type MOSFET (Metal Oxide Semiconductor Field Effect Transistor) and a p-channel conductivity type MOSFET as field effect transistors.

The vertical drive circuit 4 includes, for example, a shift register. The vertical drive circuit 4 sequentially selects desired pixel drive lines 10, supplies pulses for driving the pixels 3 to the selected pixel drive line 10, and drives each of the pixels 3 on a row-by-row basis. That is, the vertical drive circuit 4 sequentially selects and scans the pixels 3 in the pixel region 2A in the vertical direction on a row-by-row basis and supplies pixel signals from the pixels 3 based on signal charges generated by photoelectric conversion elements of the pixels 3 in response to the amount of received light to the column signal processing circuits 5 through vertical signal lines 11.

The column signal processing circuit 5 is disposed for each column of the pixels 3, for example, and performs, for each pixel column, signal processing such as noise removal on signals output from the pixels 3 in one row. For example, the column signal processing circuit 5 performs signal processing such as CDS (Correlated Double Sampling) and AD (Analog Digital) conversion for removing pixel-specific fixed pattern noise. A horizontal selection switch (not depicted) is connected between the output stage of the column signal processing circuit 5 and a horizontal signal line 12.

The horizontal drive circuit 6 includes, for example, a shift register. By sequentially outputting horizontal scan pulses to the column signal processing circuits 5, the horizontal drive circuit 6 sequentially selects the column signal processing circuits 5 and causes the respective column signal processing circuits 5 to output pixel signals subjected to signal processing to the horizontal signal line 12.

The output circuit 7 performs signal processing on pixel signals sequentially supplied from the respective column signal processing circuits 5 through the horizontal signal line 12 and outputs the resultant. As the signal processing, for example, buffering, black level adjustment, column variation correction, various types of digital signal processing, or the like can be used.

The control circuit 8 generates clock signals and control signals serving as references for the operation of the vertical drive circuit 4, the column signal processing circuits 5, the horizontal drive circuit 6, and the like on the basis of vertical synchronization signals, horizontal synchronization signals, and master clock signals. Then, the control circuit 8 outputs the generated clock signals and control signals to the vertical drive circuit 4, the column signal processing circuits 5, the horizontal drive circuit 6, and the like.

### <Pixel>

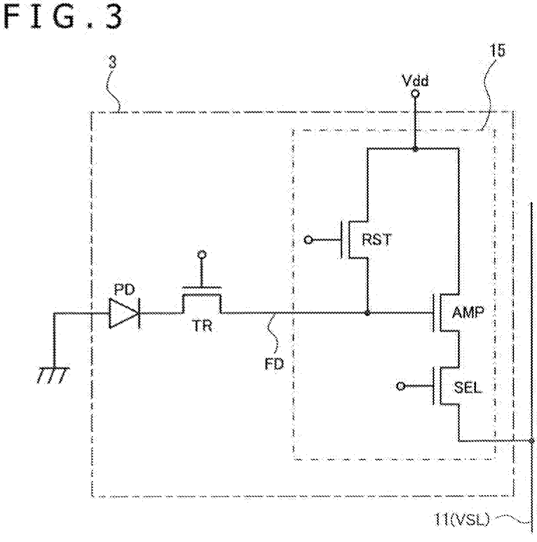

FIG. 3 is an equivalent circuit diagram depicting a configuration example of the pixel 3. The pixel 3 includes a photoelectric conversion element PD, a charge accumulation region (Floating Diffusion) FD for accumulating (holding) signal charges generated through photoelectric conversion by this photoelectric conversion element PD, and a transfer transistor TR configured to transfer the signal charges generated through photoelectric conversion by this photoelectric conversion element PD to the charge accumulation region FD. Further, the pixel 3 includes a readout circuit 15 electrically connected to the charge accumulation region FD.

The photoelectric conversion element PD generates signal charges corresponding to the amount of received light. Further, the photoelectric conversion element PD temporarily accumulates (holds) the generated signal charges. The cathode side of the photoelectric conversion element PD is electrically connected to the source region of the transfer transistor TR, and the anode side thereof is electrically connected to a reference potential line (for example, ground). A photodiode is used as the photoelectric conversion element PD, for example.

The drain region of the transfer transistor TR is electrically connected to the charge accumulation region FD. The gate electrode of the transfer transistor TR is electrically connected to a transfer transistor drive line among the pixel drive lines 10 (see FIG. 2).

The charge accumulation region FD temporarily accumulates or holds signal charges transferred from the photoelectric conversion element PD through the transfer transistor TR.

The readout circuit 15 reads out signal charges accumulated in the charge accumulation region FD and outputs pixel signals based on the signal charges. The readout circuit 15 includes, but is not limited to, an amplification transistor AMP, a selection transistor SEL, and a reset transistor RST, for example, as pixel transistors. These transistors (AMP, SEL, and RST) include MOSFETs including, for example, a gate insulating film including a silicon oxide film (SiO₂ film), a gate electrode, and a pair of main electrode regions functioning as a source region and a drain region. Further, these transistors may be MISFETs (Metal Insulator Semiconductor FETs) including a gate insulating film including a silicon nitride film (Si₃N₄ film) or a stacked film including a silicon nitride film, a silicon oxide film, and the like.

The source region of the amplification transistor AMP is electrically connected to the drain region of the selection transistor SEL, and the drain region thereof is electrically connected to a power supply line Vdd and the drain region of the reset transistor. Besides, the gate electrode of the amplification transistor AMP is electrically connected to the charge accumulation region FD and the source region of the reset transistor RST.

The source region of the selection transistor SEL is electrically connected to the vertical signal line 11 (VSL), and the drain thereof is electrically connected to the source region of the amplification transistor AMP. Besides, the gate electrode of the selection transistor SEL is electrically connected to a selection transistor drive line among the pixel drive lines 10 (see FIG. 2).

The source region of the reset transistor RST is electrically connected to the charge accumulation region FD and the gate electrode of the amplification transistor AMP, and the drain region thereof is electrically connected to the power supply line Vdd and the drain region of the amplification transistor AMP. The gate electrode of the reset transistor RST is electrically connected to a reset transistor drive line among the pixel drive lines 10 (see FIG. 2).

### <<Specific Configuration of Photodetector>>

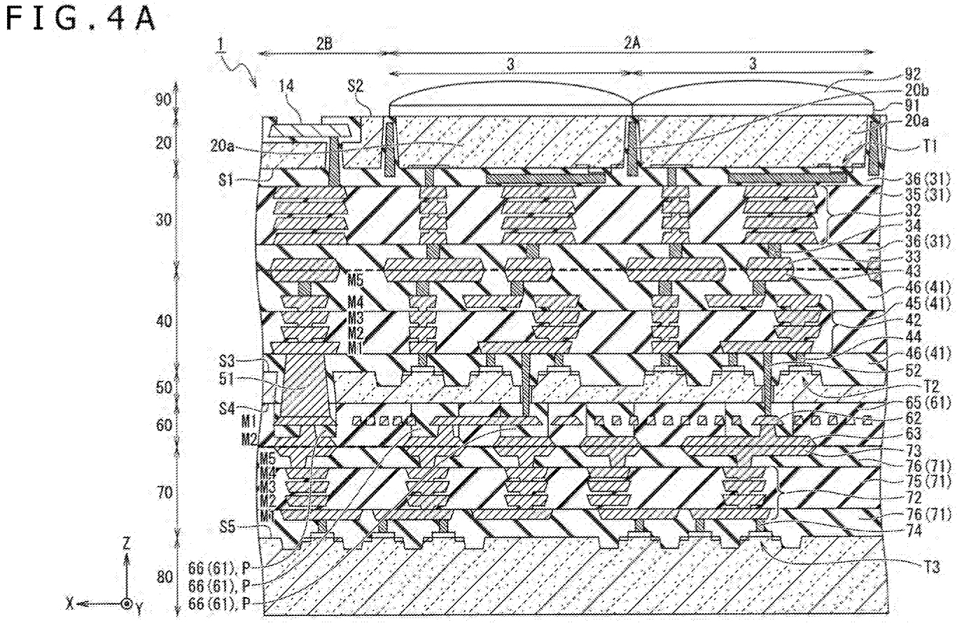

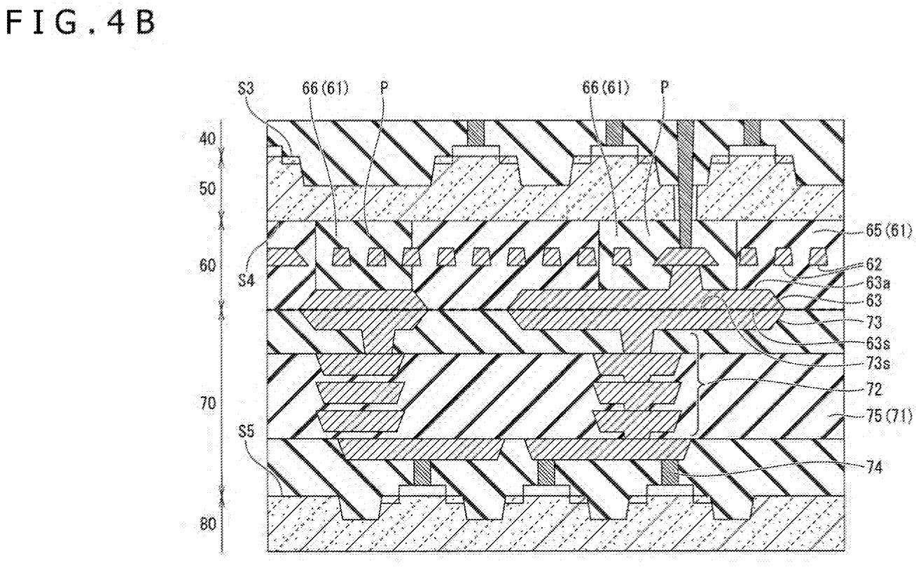

Next, the specific configuration of the photodetector 1 is described using FIG. 4A and FIG. 4B.

### <Stacked Structure of Photodetector>

As depicted in FIG. 4A, the photodetector 1 (semiconductor chip 2) has a stacked structure including a condensing layer 90, a first semiconductor layer 20, a first wiring layer 30, a second wiring layer 40, a second semiconductor layer 50, a third wiring layer 60, a fourth wiring layer 70, and a third semiconductor layer 80 stacked in this order. In the example depicted in FIG. 4A, the photodetector 1 includes three semiconductor layers, namely, the first semiconductor layer 20, the second semiconductor layer 50, and the third semiconductor layer 80.

The condensing layer 90 has, but is not limited to, a stacked structure including, for example, a color filter 91 and an on-chip lens 92 stacked in this order from a second surface S2 side of the first semiconductor layer 20. The first semiconductor layer 20 has a photoelectric conversion region described later, and one surface thereof serves as a first surface S1 and the other surface serves as the second surface S2 that is a light incident surface. The first wiring layer 30 is superposed on the first surface S1 of the first semiconductor layer 20. The second wiring layer 40 is superposed on the surface of the first wiring layer 30 on the opposite side to the surface thereof on the first semiconductor layer 20 side. The second semiconductor layer 50 includes the transistors, one surface thereof serves as a third surface S3, and the other surface serves as a fourth surface S4. The third surface S3 is superposed on the surface of the second wiring layer 40 on the opposite side to the surface thereof on the first wiring layer 30 side. The third wiring layer 60 is superposed on the fourth surface S4 of the second semiconductor layer 50. The fourth wiring layer 70 is superposed on the surface of the third wiring layer 60 on the opposite side to the surface thereof on the second semiconductor layer 50 side. A fifth surface S5 of the third semiconductor layer 80 is superposed on the surface of the fourth wiring layer 70 on the opposite side to the surface thereof on the third wiring layer 60 side.

Here, the first surface S1 of the first semiconductor layer 20 is sometimes referred to as an “element formation surface” or a “main surface,” and the second surface S2 of the first semiconductor layer 20 is sometimes referred to as a “light incident surface” or a “back surface.” Further, the third surface S3 of the second semiconductor layer 50 is sometimes referred to as an “element formation surface” or a “main surface,” and the fourth surface S4 of the second semiconductor layer 50 is sometimes referred to as a “back surface.” Moreover, the fifth surface S5 of the third semiconductor layer 80 is sometimes referred to as an “element formation surface” or a “main surface,” and the surface on the opposite side to the fifth surface S5 is sometimes referred to as a “back surface.” Here, the third surface S3 and the fifth surface S5 may be uneven as depicted in FIG. 4A.

### <First Semiconductor Layer>

The first semiconductor layer 20 includes a semiconductor substrate. The first semiconductor layer 20 includes, but is not limited to, a single-crystal silicon substrate, for example. The first semiconductor layer 20 exhibits a first conductivity type, for example, the p-type. The first semiconductor layer 20 is a semiconductor layer on the light incident surface side among the three semiconductor layers described above. More specifically, the first semiconductor layer 20 is a semiconductor layer located closest to the light incident surface side of the photodetector 1 among the three semiconductor layers described above.

Besides, in the first semiconductor layer 20, a photoelectric conversion region 20a is provided for each of the pixels 3. In the first semiconductor layer 20, for example, the island-shaped photoelectric conversion regions 20a partitioned by a separation region 20b are provided for the respective pixels 3. Note that the number of the pixels 3 is not limited to the one in FIG. 4A. The separation region 20b has, but is not limited to, a trench structure obtained by forming a separation groove in the first semiconductor layer 20 and embedding an insulating film in this separation groove, for example. In the example depicted in FIG. 4A, an insulating film and metal are embedded in the separation groove.

The photoelectric conversion region 20a includes, although not depicted, a well region of the first conductivity type, for example, the p-type, and a semiconductor region (photoelectric conversion section) of a second conductivity type, for example, the n-type, embedded in the well region. The photoelectric conversion element PD depicted in FIG. 3 is included in the photoelectric conversion region 20a, which includes the well region and the photoelectric conversion section of the first semiconductor layer 20. Further, the photoelectric conversion region 20a may be provided with a transistor T1. Moreover, the photoelectric conversion region 20a may be provided with a charge accumulation region (not depicted) that is a semiconductor region of the second conductivity type, for example, the n-type.

### <First Wiring Layer and Second Wiring Layer>

The first wiring layer 30 and the second wiring layer 40 are interposed between the semiconductor layers, more specifically, between the first semiconductor layer 20 and the second semiconductor layer 50. Further, one of the first wiring layer 30 and the second wiring layer 40 is a wiring layer on one side in the stacking direction, and the other is a wiring layer on the other side in the stacking direction.

The first wiring layer 30 includes an insulating film 31, a wiring line 32, a first connection pad 33, and a via (contact) 34. The wiring line 32 is stacked on the first connection pad 33 through the insulating film 31, as depicted in FIG. 4A. The surface of the first connection pad 33 faces the surface of the first wiring layer 30 on the opposite side to the first semiconductor layer 20 side. The via 34 connects the first semiconductor layer 20 to the wiring line 32, between the wiring lines 32, the wiring line 32 to the first connection pad 33, and the like. Further, the wiring line 32 and the first connection pad 33 may include, for example, copper and formed by a damascene method, although the present technology is not limited to these.

The insulating film 31 includes a first insulating film 35 including a first material and a second insulating film 36 including a second material. Note that, in a case where the first insulating film 35 and the second insulating film 36 are not distinguished, they are simply referred to as the “insulating film 31.” First, the second material is described. The second material is a material with a higher dielectric constant than the first material and a higher rigidity than the first material. The second material is, for example, silicon oxide (SiO₂). The first material is a low dielectric constant (Low-K) insulating material with a lower dielectric constant than the second material and a lower rigidity than the first material. Here, a description is given on the assumption that the second material is silicon oxide, and hence, the first material is an insulating material with a lower dielectric constant and a lower rigidity than a silicon oxide film. The first material is, for example, a carbon-containing silicon oxide (SiOC) film or a SiCOH film. Further, the first material may not only be the mixed material of organic and inorganic materials described above, but may also be any other inorganic or organic material. Examples of inorganic materials include fluorine-doped silicon oxide (SiOF) films, hydrogen silsesquioxane (HSQ), and the like. Examples of organic materials include parylene-based materials, polyallyl ether-based materials, and the like. Examples of mixed materials of organic and inorganic materials other than carbon-containing silicon oxide (SiOC) films and SiCOH films include methylsilsesquioxane (MSQ) and the like. Further, the first material may be a porous material obtained by introducing pores into an insulating film material. Specifically, for example, the dielectric constant of an insulating film can be reduced by reducing the density of the film through actions such as heating or drying. Besides, an increase in inter-wiring capacitance can be prevented by forming the first insulating film 35 with the first material. When an increase in inter-wiring capacitance is prevented, it is possible to achieve high-speed operation of the semiconductor elements, an increase in signal transmission speed, and a reduction in power consumption. Note that, hereinafter, in a case where the “first material” and the “second material” are described, unless otherwise defined separately, they refer to the first and second materials described above.

The second wiring layer 40 includes an insulating film 41, a wiring line 42, a second connection pad 43, and a via (contact) 44. The wiring line 42 is stacked on the second connection pad 43 through the insulating film 41, as depicted in FIG. 4A. The surface of the second connection pad 43 faces the surface of the second wiring layer 40 on the opposite side to the second semiconductor layer 50 side. The via 44 connects the second semiconductor layer 50 to the wiring line 42, between the wiring lines 42, the wiring line 42 to the second connection pad 43, and the like. Further, the wiring line 42 and the second connection pad 43 may include, for example, copper and formed by a damascene method, although the present technology is not limited to these.

The surface of the first connection pad 33 is bonded with the surface of the second connection pad 43. In this way, the surfaces of the connection pads are bonded together, thereby electrically coupling the first wiring layer 30 and the second wiring layer 40 to each other.

The insulating film 41 includes a first insulating film 45 including the first material and a second insulating film 46 including the second material. Note that, in a case where the first insulating film 45 and the second insulating film 46 are not distinguished, they are simply referred to as the “insulating film 41.”

### <Second Semiconductor Layer>

The second semiconductor layer 50 includes a semiconductor substrate. The second semiconductor layer 50 includes, but is not limited to, a single-crystal silicon substrate, for example. The second semiconductor layer 50 exhibits the first conductivity type, for example, the p-type. The second semiconductor layer 50 is provided with a transistor T2. Further, the second semiconductor layer 50 is provided with through electrodes 51 and 52 that penetrate the second semiconductor layer 50.

### <Third Wiring Layer and Fourth Wiring Layer>

The third wiring layer 60 and the fourth wiring layer 70 are interposed between the semiconductor layers, more specifically, between the second semiconductor layer 50 and the third semiconductor layer 80. Further, one of the third wiring layer 60 and the fourth wiring layer 70 is a wiring layer on one side in the stacking direction, and the other is a wiring layer on the other side in the stacking direction.

As depicted in FIG. 4A, the third wiring layer 60 includes an insulating film 61, a wiring line 62, and a third connection pad 63. The wiring line 62 is stacked on the third connection pad 63 through the insulating film 61, as depicted in FIG. 4A. As depicted in FIG. 4B, a surface 63S of the third connection pad 63 faces the surface of the third wiring layer 60 on the opposite side to the second semiconductor layer 50 side. The wiring line 62 and the third connection pad 63 may include, for example, copper and formed by a damascene method, although the present technology is not limited to these.

As depicted in FIG. 4A, the fourth wiring layer 70 includes an insulating film 71, a wiring line 72, a fourth connection pad 73, and a via (contact) 74. The wiring line 72 is stacked on the fourth connection pad 73 through the insulating film 71, as depicted in FIG. 4A. As depicted in FIG. 4B, a surface 73S of the fourth connection pad 73 faces the surface of the fourth wiring layer 70 on the opposite side to the third semiconductor layer 80 side. The via 74 connects the third semiconductor layer 80 to the wiring line 72, between the wiring lines 72, the wiring line 72 to the fourth connection pad 73, and the like. Further, the wiring line 72 and the fourth connection pad 73 may include, for example, copper and formed by a damascene method, although the present technology is not limited to these.

The surface 63S of the third connection pad 63 is bonded with the surface 73S of the fourth connection pad 73. In this way, the surfaces of the connection pads are bonded together, thereby electrically coupling the third wiring layer 60 and the fourth wiring layer 70 to each other.

The insulating film 61 includes a first insulating film 65 including the first material and a second insulating film 66 including the second material. Note that, in a case where the first insulating film 65 and the second insulating film 66 are not distinguished, they are simply referred to as the “insulating film 61.” As depicted in FIG. 4A and FIG. 4B, the second insulating film 66 including the second material penetrates the first insulating film 65 including the first material in the stacking direction. More specifically, the second insulating film 66 including the second material has a pillar-shaped portion (hereinafter also referred to as a “pillar P”) that extends along the stacking direction. This portion of the second insulating film 66 forming the pillar P penetrates the first insulating film 65 including the first material in the stacking direction. Here, the stacking direction refers to the direction in which the semiconductor layers, the wiring layers, the first insulating film 65, the second insulating film 66, and the like are stacked. Further, the portion of the second insulating film 66 forming the pillar P is provided between the third connection pad 63 and the second semiconductor layer 50. Besides, as depicted in FIG. 4B, the pillar P extends along the stacking direction, with one end in the stacking direction in contact with the third connection pad 63, more specifically, with a bottom surface 63a of the third connection pad 63, and the other end in contact with the second semiconductor layer 50, more specifically, with the fourth surface S4.

As depicted in FIG. 4A, the insulating film 71 includes a first insulating film 75 including the first material and a second insulating film 76 including the second material. Note that, in a case where the first insulating film 75 and the second insulating film 76 are not distinguished, they are simply referred to as the “insulating film 71.”

### <Third Semiconductor Layer>

The third semiconductor layer 80 includes a semiconductor substrate. The third semiconductor layer 80 includes a single-crystal silicon substrate of the first conductivity type, for example, the p-type. The third semiconductor layer 80 is provided with a transistor T3.

<Position at which Pillar is Provided>

The first insulating films 35, 45, 65, and 75 including the first material are provided at locations at which the wiring lines are densely provided in the wiring layers. With this, an increase in wiring capacitance can be prevented. To prevent an increase in wiring capacitance, it is preferable to provide the first insulating films 35, 45, 65, and 75 in wide regions. Thus, the first insulating films 35, 45, 65, and 75 are arranged to occupy wider regions in the horizontal direction of the wiring layers.

Further, the pillar P is provided to prevent insufficient bonding characteristics between the connection pads. The pillar P is the pillar-shaped portion of the second insulating film 66 that extends along the stacking direction. The pillar P with such a shape is provided, thereby making it possible to reduce the region occupied by the second insulating film 66 in the region in which the wiring lines are densely provided. In this way, the pillar P is provided only at necessary locations.

### <<Method of Manufacturing Photodetector>>

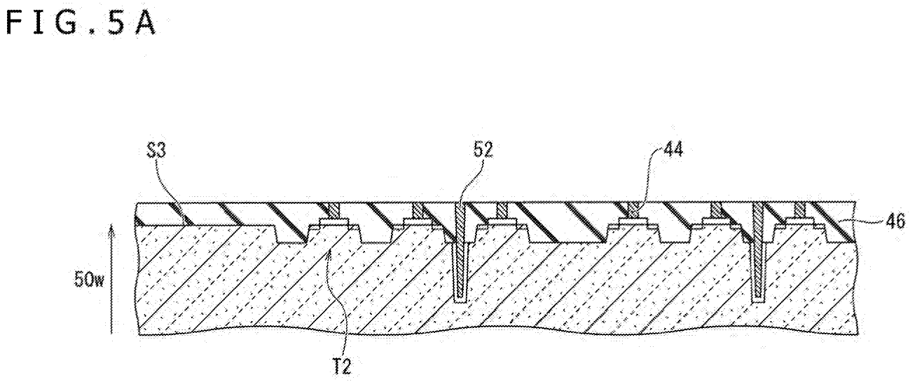

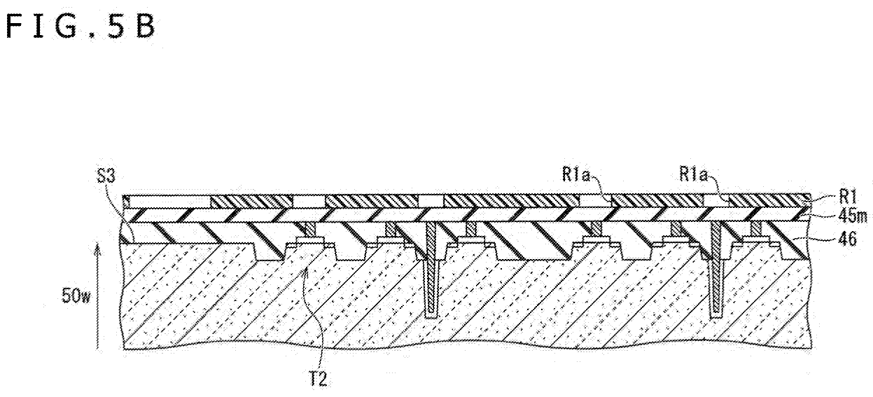

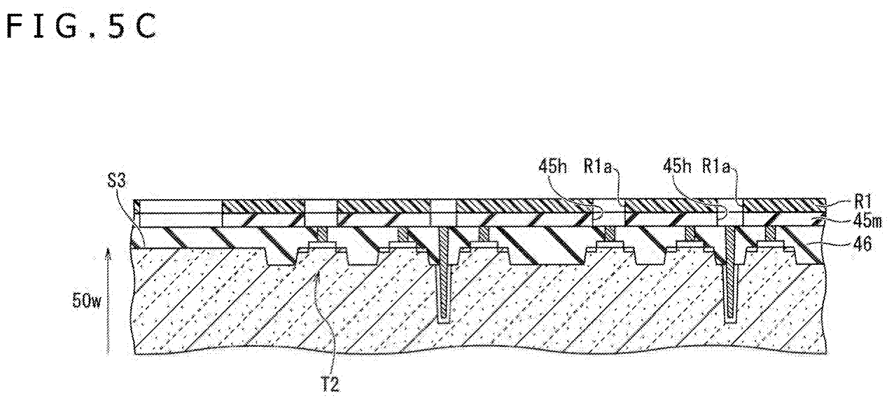

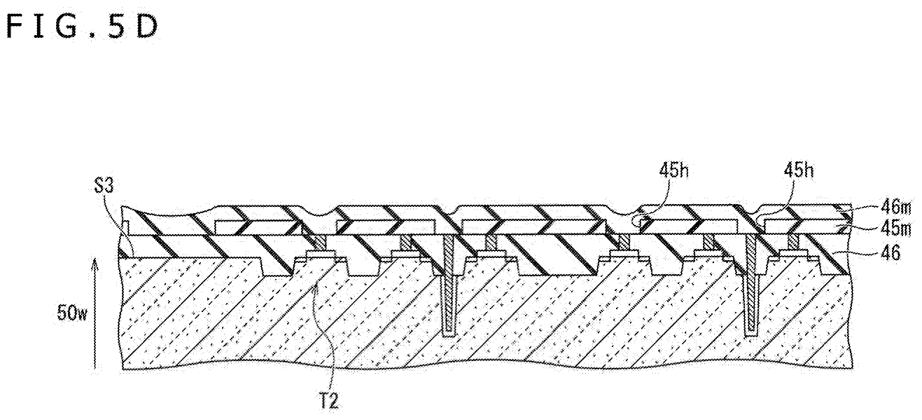

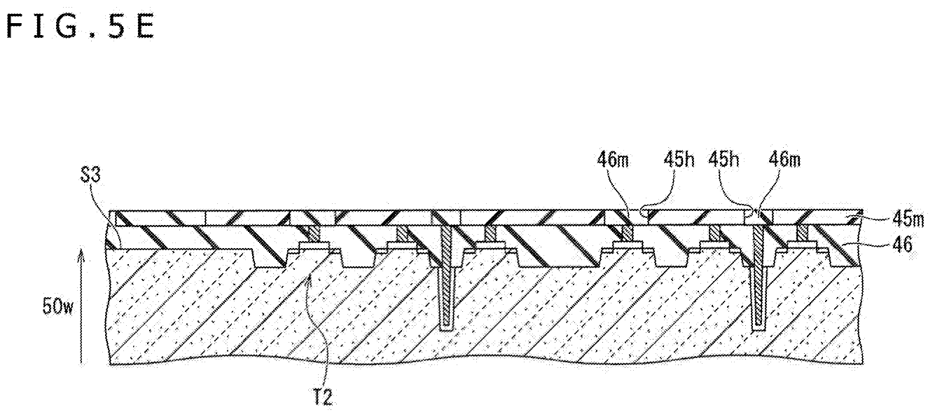

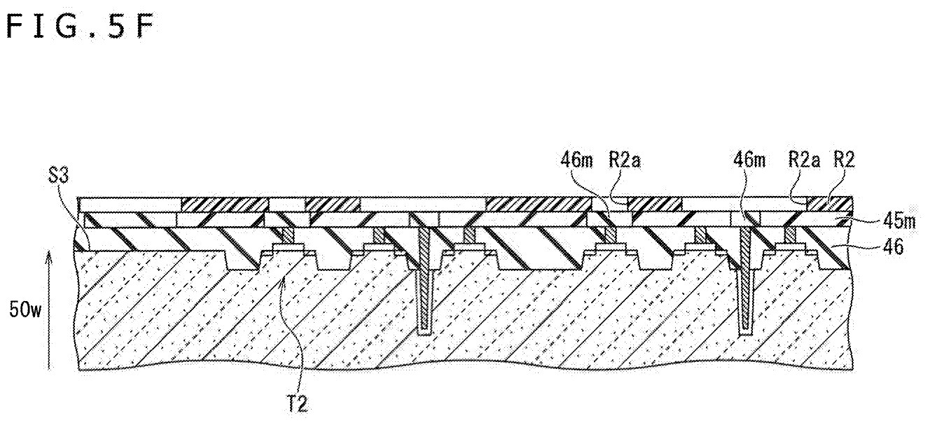

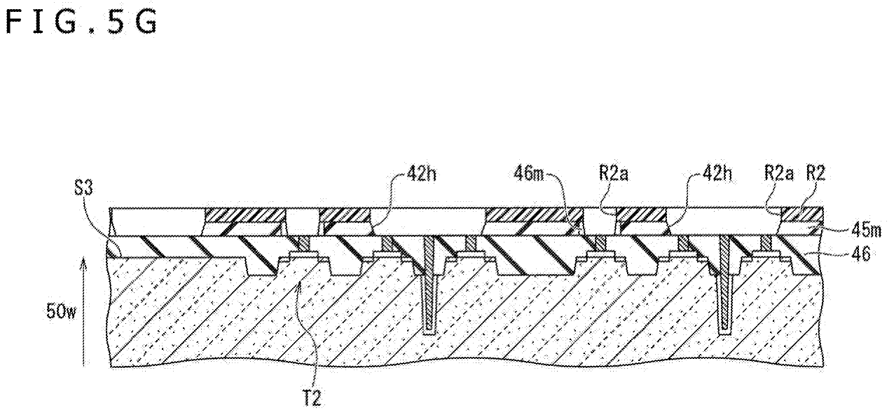

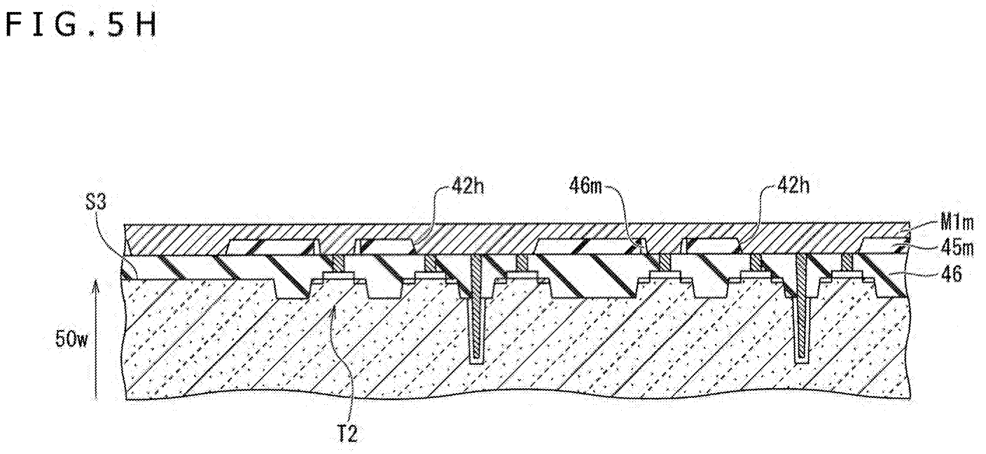

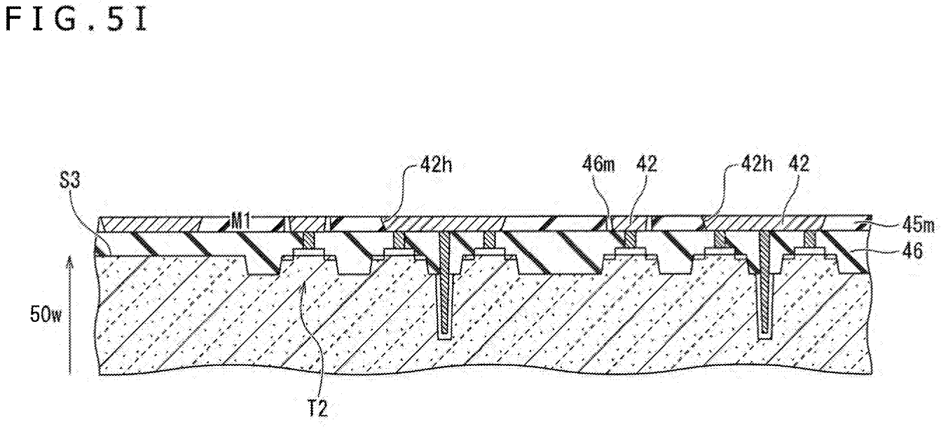

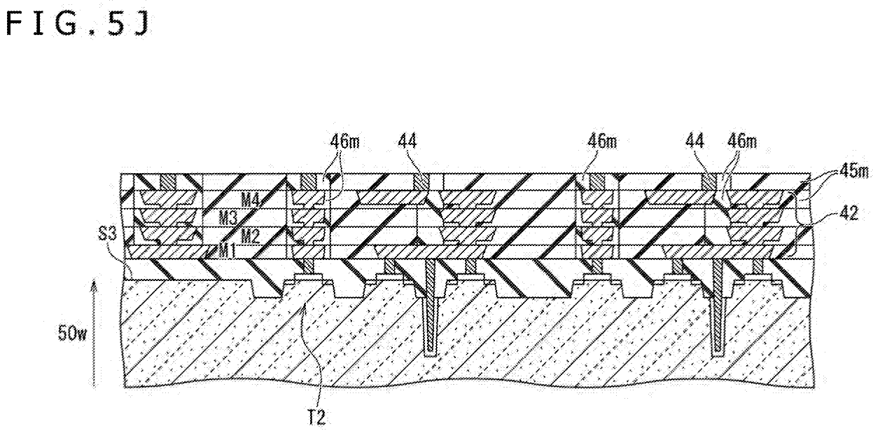

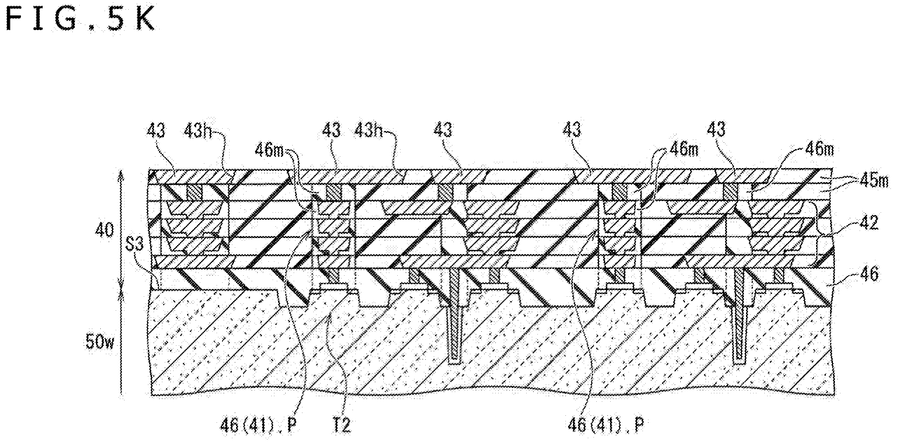

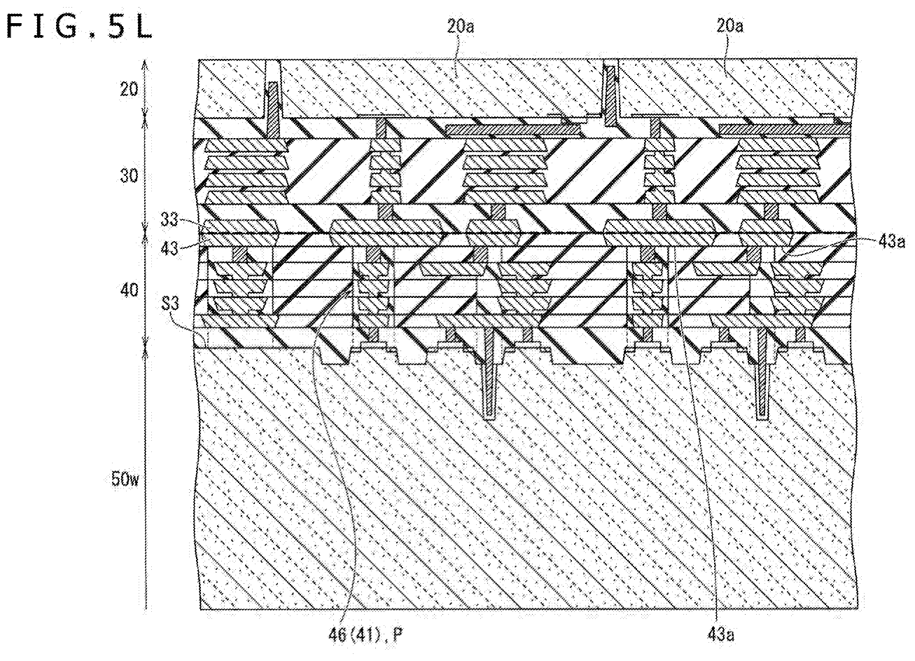

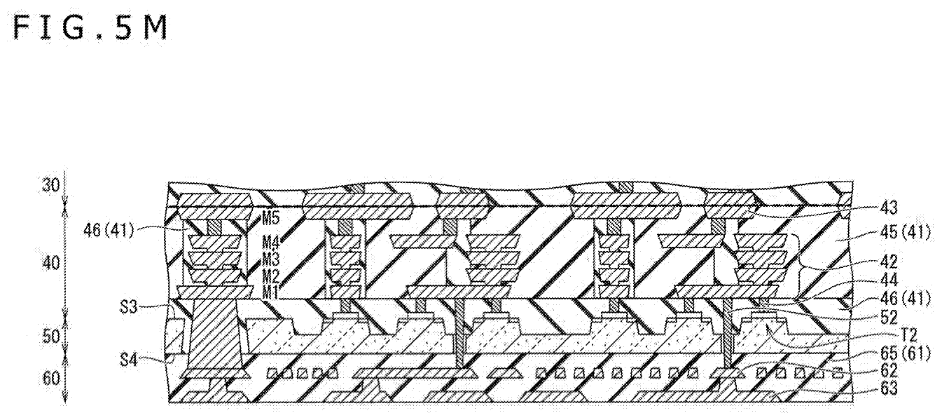

Now, with reference to FIG. 5A to FIG. 5N, a method of manufacturing the photodetector 1 is described. Note that, in the example of the photodetector 1 depicted in FIG. 4A and FIG. 4B, the pillar P is provided in the third wiring layer 60. However, here, the method of manufacturing the photodetector 1 is described for an example in which the pillar P is provided in the second wiring layer 40.

First, as depicted in FIG. 5A, elements such as the transistor T2 are formed on the third surface S3 side of a second semiconductor layer 50w of the first conductivity type, for example, the p-type. Then, on the third surface S3, a portion of the second wiring layer 40 is formed. More specifically, on the third surface S3, the second insulating film 46, the via 44, the through electrode 52, and the like are formed. The second insulating film 46 depicted in FIG. 5A includes the second material. The second insulating film 46 is a passivation film, for example.

Next, as depicted in FIG. 5B, a film 45m including the first material is stacked on the exposed surface of the second insulating film 46. Then, a resist pattern R1 is formed on the exposed surface of the film 45m using a known lithography technique. After that, using a known etching technique, the portion of the film 45m exposed from an opening portion R1a of the resist pattern R1 is etched, with the resist pattern R1 as a mask. With this etching, a hole 45h depicted in FIG. 5C is formed. After that, the resist pattern R1 is removed.

Then, as depicted in FIG. 5D, a film 46m including the second material is stacked to fill the hole 45h. Then, as depicted in FIG. 5E, excess portions of the film 46m are removed by a CMP (Chemical Mechanical Polishing) method. More specifically, the exposed surface of the film 46m is polished by a CMP method to flatten the exposed surface and remove the portion of the film 46m other than the portion embedded in the hole 45h. With this, an insulating film in which the different insulating materials are adjacent to each other in the direction vertical to the stacking direction is formed.

Next, as depicted in FIG. 5F, a resist pattern R2 is formed on the exposed surface of the insulating film, more specifically, on the exposed surfaces of the film 45m and the film 46m, using a known lithography technique. After that, as depicted in FIG. 5G, using a known etching technique, the portion of the insulating film exposed from an opening portion R2a of the resist pattern R2 is etched, with the resist pattern R2 as a mask. With this etching, an opening 42h is formed. After that, the resist pattern R2 is removed.

After that, as depicted in FIG. 5H, a metal film M1m is stacked on the inner wall of the opening 42h and the exposed surface of the insulating film. Then, as depicted in FIG. 5I, excess portions of the metal film M1m are removed by a CMP method. With this, the wiring line 42 belonging to a metal layer M1 is formed.

Thereafter, for each metal layer, processes like the processes depicted in FIG. 5B to FIG. 5I are repeated. With this, as depicted in FIG. 5J, the wiring lines 42 belonging to the metal layer M1 to a metal layer M4 are formed. Further, for the layer in which the via 44 is provided, processes like the processes depicted in FIG. 5B to FIG. 5E are performed, and then the via 44 is formed by known methods. Then, in this way, the layers directly below the layer where the second connection pad 43 is provided are formed.

Next, as depicted in FIG. 5K, the film 45m including the first material is stacked on the exposed surface of the insulating film, and then the second connection pad 43 is formed. More specifically, after stacking the film 45m, processes like the processes depicted in FIG. 5F to FIG. 5I are performed to form the second connection pad 43. The second connection pad 43 is embedded in an opening 43h formed in the film 45m. With this, the second wiring layer 40 is almost completed. The films 46m are stacked along the stacking direction, as depicted in FIG. 5K. Besides, the pillar P is configured by the films 46m stacked in this way and the portion of the second insulating film 46, which includes the second material, located between the films 46m and the second semiconductor layer 50w.

Then, as depicted in FIG. 5L, the second semiconductor layer 50w having stacked thereon the second wiring layer 40 is bonded with the first semiconductor layer 20 having stacked thereon the first wiring layer 30, which is separately prepared. More specifically, the surface of the first wiring layer 30 on the opposite side to the first semiconductor layer 20 side is superposed and bonded with the surface of the second wiring layer 40 on the opposite side to the second semiconductor layer 50w side. After that, the bonded structure including the first wiring layer 30 to the second semiconductor layer 50w is subjected to heat treatment. With this heat treatment, the metal that constitutes the first connection pad 33 and the second connection pad 43 expands. Further, the pillar P extends along the stacking direction between a bottom surface 43a of the second connection pad 43 and the third surface S3 of the second semiconductor layer 50. More specifically, one end in the stacking direction of the pillar P is in contact with the bottom surface 43a of the second connection pad 43, and the other end is in contact with the third surface S3 of the second semiconductor layer 50. Thus, the pressing force generated during the expansion of the metal that constitutes the first connection pad 33 and the second connection pad 43 can be prevented from escaping to the insulating film side. With this, during the expansion of the metal that constitutes the first connection pad 33 and the second connection pad 43, the pressing force acts in the intended directions to make the connection pads push against each other, thereby making it possible to prevent insufficient bonding characteristics between the connection pads. In this way, the surface of the first connection pad 33 provided in the first wiring layer 30 is bonded with the surface of the second connection pad 43 provided in the second wiring layer 40.

Then, back grinding or the like is performed on the back surface side of the second semiconductor layer 50w to reduce the thickness of the second semiconductor layer 50w. With this, as depicted in FIG. 5M, a portion that is to serve as the second semiconductor layer 50 is left. Then, the third wiring layer 60 is stacked on the fourth surface S4 side of the second semiconductor layer 50. After that, although the order of processes is not limited to the following, the second semiconductor layer 50 having stacked thereon the third wiring layer 60 is bonded with the third semiconductor layer 80 having stacked thereon the fourth wiring layer 70, which is separately prepared. Then, the condensing layer 90 is formed on the light incident surface side. With this, the photodetector 1 depicted in FIG. 5N is almost completed. The photodetector 1 is formed in each of a plurality of chip formation regions partitioned by scribe lines (dicing lines) on a semiconductor substrate. Then, the plurality of chip formation regions is divided along the scribe lines into individual components, thereby forming the semiconductor chip 2 having mounted thereon the photodetector 1.

### Main Effect of First Embodiment

Hitherto, as described above, in a case where connection pads are formed using a CMP method, there have been cases where the metal that constitutes the connection pads is more polished than the insulating films. Even in such a case, by performing heat treatment on the wiring layers after superposing and bonding the wiring layers together, it is possible to expand the metal that constitutes the connection pads with heat, thereby bonding the connection pads together. However, when it is attempted to densely arrange connection pads, the dimensions of the connection pads are reduced, and the volume thereof is also reduced. Besides, as the volume of the connection pads is reduced, the amount of expansion of the metal that constitutes the connection pads is also reduced.

Meanwhile, to reduce the parasitic capacitance of wiring lines, it is considered to use a low dielectric constant insulating material with a low dielectric constant as the material of the insulating films forming the wiring layers. However, such low dielectric constant insulating materials have a lower rigidity than silicon oxide, and in some cases, the Young's modulus of the materials is only approximately 1/20 of that of silicon oxide. In a case where such a low dielectric constant insulating material is provided between the bottom surface of a connection pad and a semiconductor layer, there has been a risk that, since the low dielectric constant insulating material can be deformed more easily than materials with high rigidity, rather than acting on the connection pad that is a bonding partner, the pressing force generated during the expansion of the metal that constitutes the connection pad escapes to the low dielectric constant insulating film located on the opposite side to the bonding partner. That is, there has been a risk that the low dielectric constant insulating material is deformed to absorb the pressing force.

In contrast to this, in the photodetector 1 according to the first embodiment of the present technology, as depicted in FIG. 4B, the insulating film 61 includes the first insulating film 65 including the first material and the second insulating film 66 which includes a material with a higher rigidity than the first material and penetrates the first insulating film 65 in the stacking direction. The first insulating film 65 is provided between the third connection pad 63 and the second semiconductor layer 50. Besides, the pillar-shaped portion of the second insulating film 66 (pillar P) extends along the stacking direction and has one end in the stacking direction in contact with the third connection pad 63 and the other end in contact with the second semiconductor layer 50. In this way, the pillar P is selectively provided to extend along the stacking direction without interruption from the bottom surface 63a of the third connection pad 63 to the fourth surface S4 of the second semiconductor layer 50 with sufficiently high Young's modulus, and hence, the pressing force generated during the expansion of the metal that constitutes the third connection pad 63 and the fourth connection pad 73 can be prevented from escaping to the third wiring layer 60 side. With this, during the expansion of the metal that constitutes the third connection pad 63 and the fourth connection pad 73, the pressing force acts in the intended directions to make the connection pads push against each other, thereby making it possible to prevent insufficient bonding characteristics between the connection pads.

Moreover, since the low dielectric constant insulating films can be provided in the wiring layers, an increase in wiring capacitance can be prevented.

Note that, in the first embodiment, the pillar P is provided only in the single wiring layer, but the present technology is not limited to this. The pillar P is desirably applied to all the first wiring layer 30, the second wiring layer 40, the third wiring layer 60, and the fourth wiring layer 70. Further, the pillar P may be applied to any of the wiring layers described above, or to at least one of the wiring layers. Further, the plurality of pillars P may be provided for the single third connection pad 63.

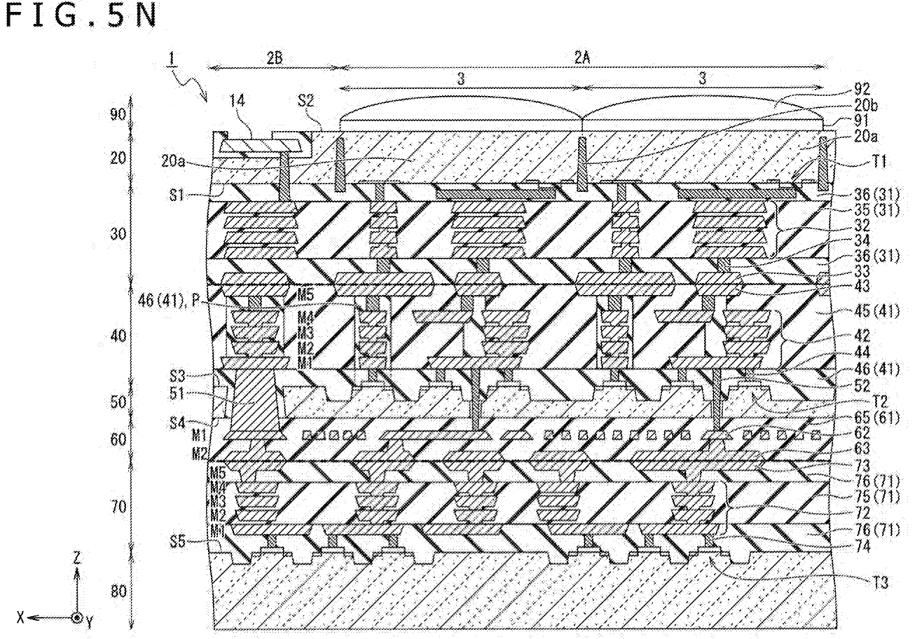

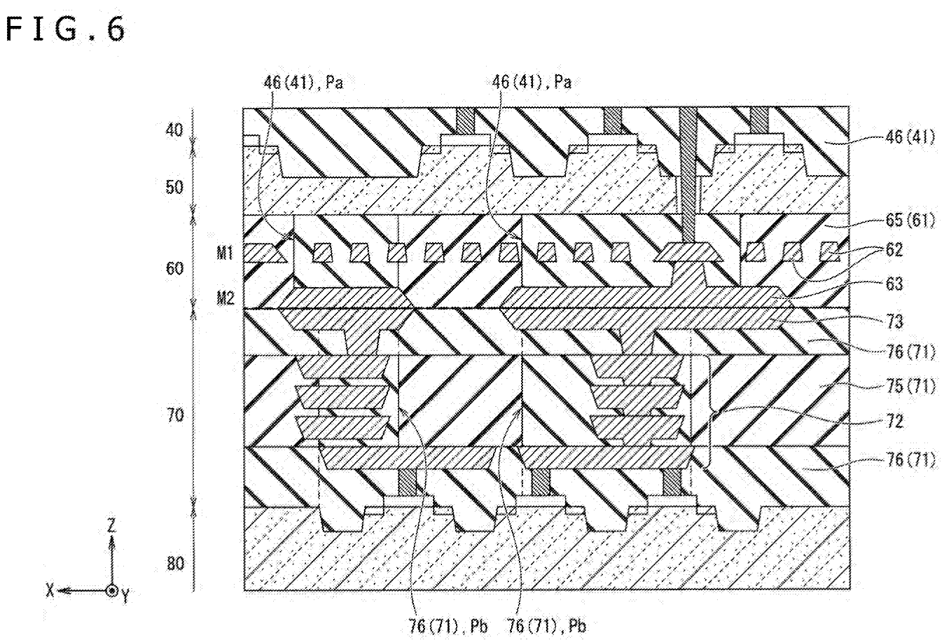

Further, FIG. 6 depicts an example in which a pillar Pa and a pillar Pb are provided in the third wiring layer 60 and the fourth wiring layer 70, which are bonded together, respectively. In this way, the pillar Pa and the pillar Pb sandwich a pair of connection pads. More specifically, the pillar Pa is provided to extend without interruption from the surface of the second semiconductor layer 50 to the bottom surface of the third connection pad 63, while the pillar Pb is provided to extend without interruption from the surface of the third semiconductor layer 80 to the bottom surface of the fourth connection pad 73. Consequently, the pressing force generated during the expansion of the metal that constitutes the third connection pad 63 and the fourth connection pad 73 can be prevented from escaping to the third wiring layer 60 side and the fourth wiring layer 70 side. With this, the connection pads push against each other more strongly, thereby making it possible to prevent insufficient bonding characteristics between the connection pads more effectively.

### First Modified Example of First Embodiment

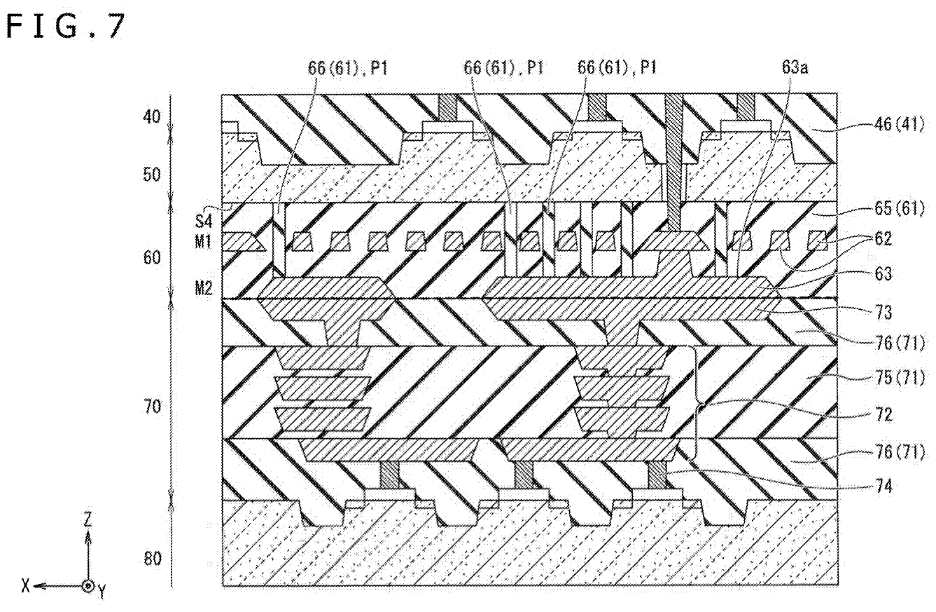

A first modified example of the first embodiment of the present technology depicted in FIG. 7 is described below. The photodetector 1 according to the first modified example of the first embodiment is different from the above-mentioned photodetector 1 according to the first embodiment in being provided with a pillar P1 instead of the pillar P, while the configuration of the photodetector 1 other than that is basically similar to the configuration of the above-mentioned photodetector 1 of the first embodiment. Note that the components already described are denoted by the same reference signs, and the description thereof is omitted.

Here, an example in which the pillar P1 is provided in the third wiring layer 60 is described. The portion of the second insulating film 66 including the second material, which forms the pillar P1 (in other words, the portion of the second insulating film 66 formed in a pillar shape), penetrates the first insulating film 65 including the first material in the stacking direction. As in the case of the first embodiment, the pillar P1 extends along the stacking direction, with one end in the stacking direction in contact with the third connection pad 63, more specifically, with the bottom surface 63a of the third connection pad 63, and the other end in contact with the second semiconductor layer 50, more specifically, with the fourth surface S4.

Further, the pillar P1 is provided at a position that does not overlap with the wiring line 62 formed in the insulating film 61 in the stacking direction, that is, at a position that does not overlap with the wiring line 62 in plan view. Thus, the pillar P1 penetrates the insulating film located between the wiring lines 62. Further, the pillar P1 is provided with a smaller width than the pillar P depicted in FIG. 4A and the like. With this, the pillar P1 can be provided at a position that does not overlap with the wiring line 62 in plan view. Further, one or more pillars P1 may be provided for the single third connection pad 63. The plurality of pillars P1 is provided for the single third connection pad 63, thereby making it possible to prevent insufficient rigidity between the third connection pad 63 and the second semiconductor layer 50 even with the pillar P1 with a smaller width.

### <<Method of Manufacturing Photodetector>>

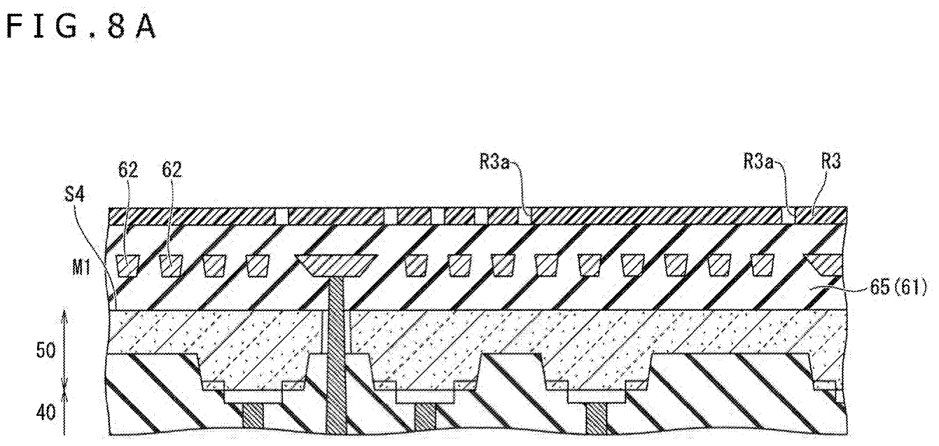

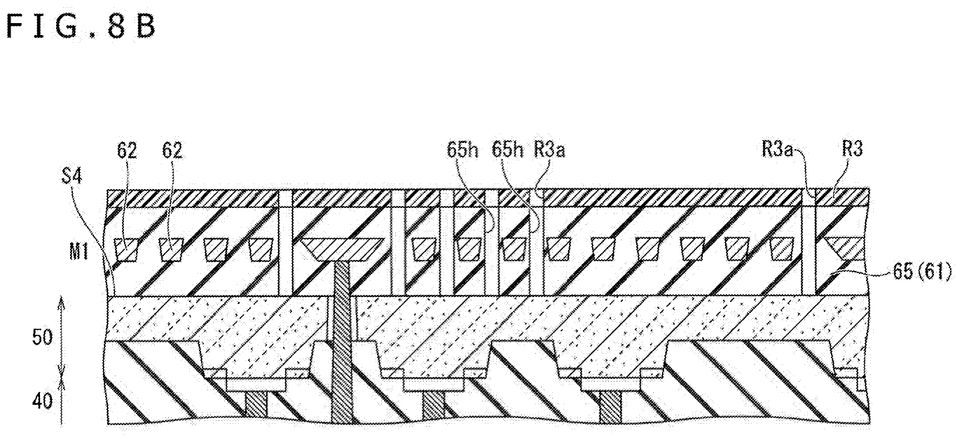

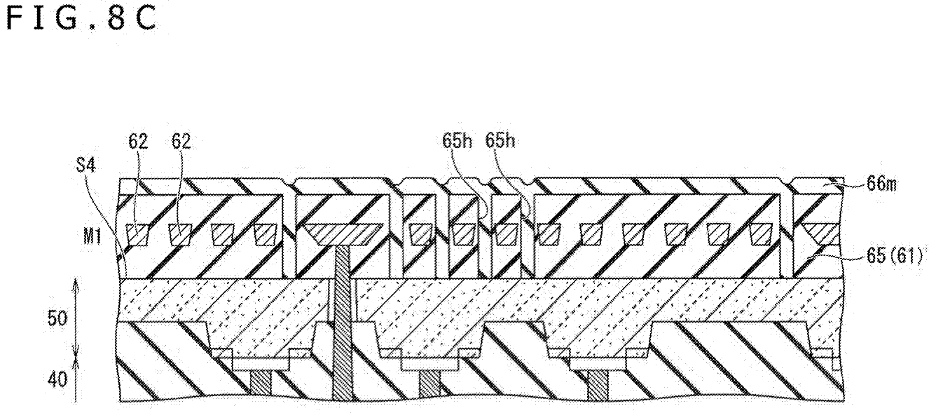

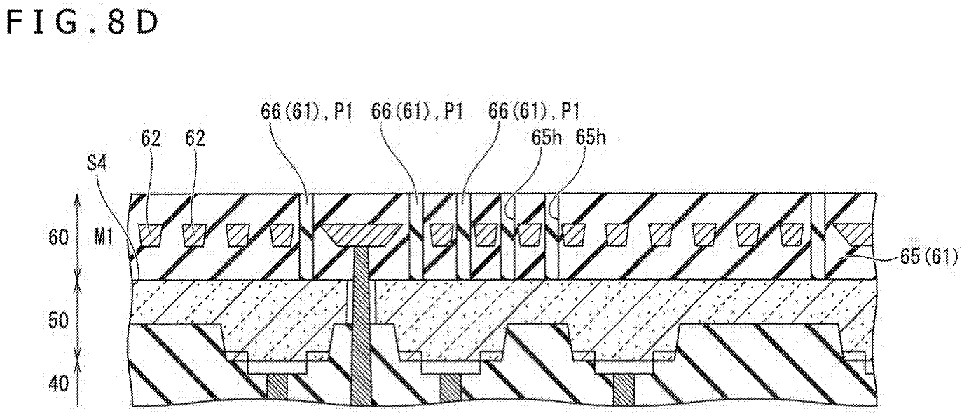

Now, with reference to FIG. 8A to FIG. 8D, a method of manufacturing the photodetector 1 is described. Note that, here, only the process of forming the pillar P1 is described.

First, as depicted in FIG. 8A, a portion of the second wiring layer 40 is formed on the fourth surface S4 side of the second semiconductor layer 50. More specifically, the wiring line 42 belonging to the metal layer M1 is formed, and the first insulating film 65 is further deposited on the exposed surface of the structure. That is, the layers up to the one just before the layer that is provided with the third connection pad 63 are formed. After that, a resist pattern R3 is formed on the exposed surface by use of a known photolithography technique.

Next, as depicted in FIG. 8B, by use of a known etching technique, the portion of the first insulating film 65 exposed from an opening portion R3a of the resist pattern R3 is etched, with the resist pattern R3 as a mask. With this etching, a hole 65h is formed. The hole 65h penetrates the first insulating film 65, and the bottom surface thereof reaches the second semiconductor layer 50. After that, the resist pattern R3 is removed.

Then, as depicted in FIG. 8C, a film 66m including the second material is stacked to fill the hole 65h. Then, as depicted in FIG. 8D, excess portions of the film 66m are removed by a CMP method. More specifically, the exposed surface of the film 66m is polished by a CMP method to flatten the exposed surface and remove the portion of the film 66m other than the portion embedded in the hole 65h. With this, an insulating film in which the different insulating materials are adjacent to each other in the direction vertical to the stacking direction is formed. Then, the pillar P1 is formed. After that, although not depicted, the third connection pad 63 is formed by known methods.

### Main Effect of First Modified Example of First Embodiment

Even with this photodetector 1 according to the first modified example of the first embodiment, similar effects to the above-mentioned photodetector 1 according to the first embodiment can be obtained.

Further, in this photodetector 1 according to the first modified example of the first embodiment, since the pillar P1 can be formed by performing photolithography and etching once each, the number of processes can be reduced compared to the case of the first embodiment.

Moreover, in this photodetector 1 according to the first modified example of the first embodiment, since the pillar P1 is provided while avoiding the wiring lines, a greater amount of the first material (low dielectric constant insulating material) between the wiring lines can be left, so that an increase in wiring capacitance can be prevented more effectively.

Note that both the pillar P1 of the present embodiment and the pillar P of the first embodiment may be provided in the single photodetector 1. The pillar P1 and the pillar P may be selectively used for each wiring layer, for example, the pillar P is provided in the first wiring layer 30 of the photodetector 1, and the pillar P1 is provided in the second wiring layer 40. For example, in a wiring layer in which there is insufficient spacing between the wiring lines, the pillar P, which is less likely to be restrained in terms of wiring arrangement, may be provided. In a wiring layer in which a more reduction in wiring capacitance is desired and it is possible to avoid the wiring lines, the pillar P1 may be provided.

### Second Modified Example of First Embodiment

A second modified example of the first embodiment of the present technology is described below. The photodetector 1 according to the second modified example of the first embodiment is different from the above-mentioned photodetector 1 according to the first embodiment in the second material, while the configuration of the photodetector 1 other than that is basically similar to the configuration of the above-mentioned photodetector 1 of the first embodiment. Note that the components already described are denoted by the same reference signs, and the description thereof is omitted. Further, here, FIG. 4A and FIG. 4B are reused for description.

In the first embodiment, the second material is silicon oxide, but in the second modified example of the first embodiment, the second material is silicon nitride. Here, the Young's modulus of silicon oxide is 80 GPa, while the Young's modulus of silicon nitride is 200 GPa. That is, silicon nitride has a higher rigidity than silicon oxide. Thus, the pressing force generated during the expansion of the metal that constitutes the first connection pad 33 and the second connection pad 43 can be prevented from escaping to the insulating film side more effectively. With this, the connection pads push against each other more strongly, thereby making it possible to prevent insufficient bonding characteristics between the connection pads more effectively.

Further, the linear expansion coefficient of silicon oxide is 0.5 ppm/K, while the linear expansion coefficient of silicon nitride is 2.9 ppm/K. That is, the amount of expansion due to heat of silicon nitride is greater than that of silicon oxide. Thus, in a case where the pillar P includes silicon nitride, as compared to a case where the pillar P includes silicon oxide, not only the pressing force can be prevented from escaping to the insulating film side more effectively, but also the force for pressing the third connection pad 63 toward the fourth connection pad 73 increases. Thus, with materials with a greater linear expansion coefficient, the deterioration of contact characteristics between the connection pads can be prevented more effectively.

### Main Effect of Second Modified Example of First Embodiment

Even with this photodetector 1 according to the second modified example of the first embodiment, similar effects to the above-mentioned photodetector 1 according to the first embodiment can be obtained.

Further, since the second material of the pillar P of this photodetector 1 according to the second modified example of the first embodiment is a material with a higher rigidity, the pressing force generated during the expansion of the metal that constitutes the connection pads can be prevented from escaping to the insulating film side more effectively.

Moreover, since the second material of the pillar P of this photodetector 1 according to the second modified example of the first embodiment is a material with a greater linear expansion coefficient, the force for pressing one connection pad toward the other connection pad increases. Thus, with materials with a greater linear expansion coefficient, the deterioration of contact characteristics between the connection pads can be prevented more effectively.

Note that the second material of the pillar P of the above-mentioned photodetector 1 according to the second modified example of the first embodiment is silicon nitride, but the present technology is not limited to this. For example, the pillar P may have both a portion (or layer) including silicon nitride and a portion (or layer) including silicon oxide. In this way, the pillar P may have portions (or layers) including different materials as long as the materials satisfy the conditions for the second material.

Further, an example in which the pillar P depicted in FIG. 4A and the like includes silicon nitride has been described in the second modified example of the first embodiment, but the present technology is not limited to this. The pillar P1 depicted in FIG. 7 and the like may include silicon nitride. Moreover, the pillar P1 may have both a portion (or layer) including silicon nitride and a portion (or layer) including silicon oxide. The pillar P1 may have portions (or layers) including different materials as long as the materials satisfy the conditions for the second material. Even in that case, similar effects to the photodetector 1 according to the second modified example of the first embodiment can be obtained.

### Second Embodiment

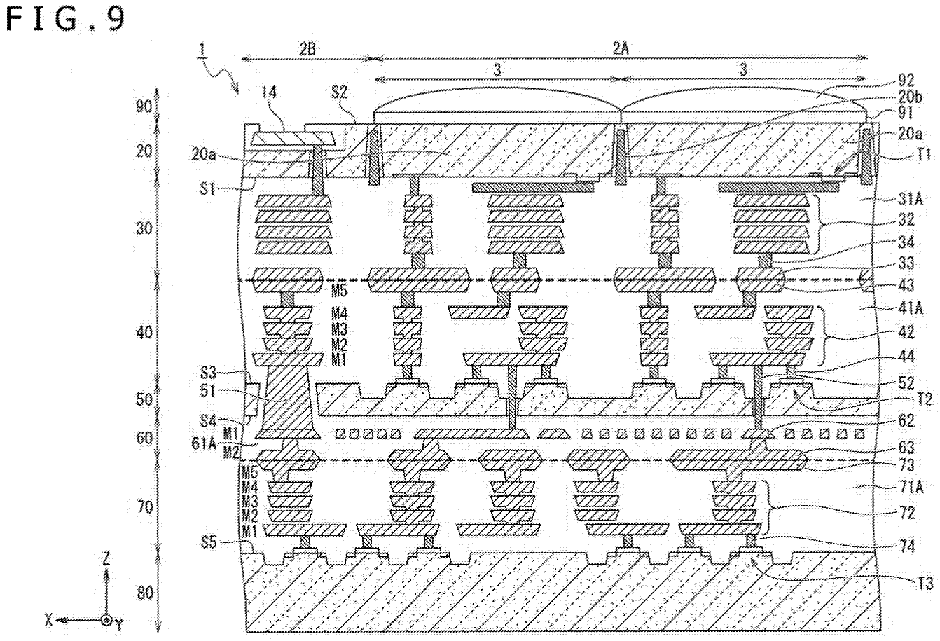

A second embodiment of the present technology depicted in FIG. 9 and FIG. 10 is described below. The photodetector 1 according to the second embodiment is different from the above-mentioned photodetector 1 according to the first embodiment in the configuration of the connection pad, while the configuration of the photodetector 1 other than that is basically similar to the configuration of the above-mentioned photodetector 1 of the first embodiment. Note that the components already described are denoted by the same reference signs, and the description thereof is omitted.

### <Insulating Film>

As depicted in FIG. 9, the first wiring layer 30 includes an insulating film 31A, the second wiring layer 40 includes an insulating film 41A, the third wiring layer 60 includes an insulating film 61A, and the fourth wiring layer 70 includes an insulating film 71A. The insulating films 31A, 41A, 61A, and 71A include, but are not limited to, layers including, for example, silicon oxide.

### <Connection Pad>

FIG. 10 is an explanatory diagram depicting the configuration of a connection pad. The connection pad depicted in FIG. 10 is here referred to as a “connection pad A” for convenience. The configuration of the connection pad A can be applied to any of the first connection pad 33, the second connection pad 43, the third connection pad 63, and the fourth connection pad 73 depicted in FIG. 9. The configuration of the connection pad A is desirably applied to all the first connection pad 33, the second connection pad 43, the third connection pad 63, and the fourth connection pad 73, but the configuration may be applied to at least one of these connection pads.

As depicted in FIG. 10, the connection pad A includes a first portion “a,” a second portion b, and a seed layer c. Besides, the connection pad A is provided within an opening e provided in an insulating film d. Further, a barrier metal layer f is provided between the connection pad A and the insulating film d.

The first portion “a” includes a first metal and forms the surface of the connection pad A. When the connection pad A is subjected to heat treatment, the first portion “a” thermally expands. More specifically, it is assumed that, in the state before heat treatment, the first portion “a” occupies a region from a position closer to a bottom e1 of the opening e to the height of the dashed line in the opening e, as depicted in FIG. 10, for example, although the present technology is not limited to this. Then, when heat treatment is performed on the connection pad A, the first portion “a” thermally expands in the direction indicated by an arrow al from the height of the dashed line to protrude from a surface d1 of the insulating film d. Examples of the first metal include, but are not limited to, copper (Cu). Here, a description is given on the assumption that the first metal is copper.

The second portion b is provided between the first portion “a” and the insulating film d. The second portion b includes a second metal that is more easily plastically deformed than the first metal. In other words, the second metal has a lower rigidity than the first metal. Metals that are easily plastically deformed are metals that are easily deformed when receiving force and have low yield stress or resistance. Metals have the property of not returning to their original shapes when deformed once through the application of force at a certain level or greater. Yield stress represents the force at which the plastic deformation of a material starts. Further, regarding metals whose yield stress is not clear, the difficulty in plastic deformation is evaluated as resistance in some cases. Besides, metals that are more easily plastically deformed are deformed with smaller forces.

When the connection pad A is subjected to heat treatment, the second portion b is plastically deformed. More specifically, when the connection pad A is subjected to heat treatment, among a sidewall portion b1 and a bottom portion b2 of the second portion b, the sidewall portion b1 is mainly plastically deformed. That is, it is sufficient that the second portion b is provided at least between the side surface of the first portion “a” and the insulating film d. Here, the bottom portion b2 is a portion located closer to the bottom e1 of the opening e, and the sidewall portion b1 is a portion located closer to a sidewall e2 of the opening e.

It is assumed that, in the state before heat treatment, the sidewall portion b1 occupies a region from the bottom e1 side of the opening e to the height of the dashed line in the opening e, as depicted in FIG. 10, for example, although the present technology is not limited to this. Then, when heat treatment is performed on the connection pad A, by being dragged by the thermal expansion of the first portion “a,” the sidewall portion b1 is plastically deformed to extend in the direction indicated by an arrow b3 from the height of the dashed line, together with the first portion “a.” Further, the second portion b may thermally expand while being plastically deformed. The sidewall portion b1 may thermally expand in the direction indicated by the arrow b3 while being plastically deformed.

When heat treatment is performed on the connection pad A, a surface b11 of the sidewall portion b1 closer to the barrier metal layer f is restrained by the barrier metal layer f. This is because the amount of deformation of the barrier metal layer f due to heat is small. In contrast to this, a surface b12 of the sidewall portion b1 closer to the first portion “a” receives tension due to the thermal expansion of the first portion “a.” In this way, different forces act on the surface b11 and the surface b12, resulting in plastic deformation of the sidewall portion b1.

Examples of the second metal can include aluminum (Al), aluminum-copper (AlCu) alloys, aluminum-silicon (AlSi) alloys, and the like. These metals are metals that are easily plastically deformed at room temperature. Further, since the first metal expands during heat treatment, the second metal may be a metal that is more easily plastically deformed than the first metal when heated. More specifically, a metal that is difficult to plastically be deformed at room temperature but more easily plastically deformed than the first metal at a temperature at which the connection pad is subjected to heat treatment can be utilized as the second metal.

Examples of metals that are more easily plastically deformed than the first metal when heated include metals with a low melting point. Examples of metals with a low melting point can include cadmium (Cd), tin (Sn), tantalum (Tl), and lead (Pb). The melting points of these metals are lower than 400° C.

Further, the rigidity of metals generally decreases as the metals are heated toward their melting points. Thus, metals with a lower rigidity than the first metal at the temperature for connection pad heat treatment can be considered as metals that are more easily plastically deformed than the first metal when heated, even when their melting points are high. Examples of such metals can include antimony (Sb), ytterbium (Yb), calcium (Ca), silver (Ag), germanium (germanium), strontium (Sr), cerium (Ce), lead-copper (PbCu) alloys, and the like. The melting points of these metals are lower than 1,000° C. Note that the melting point of aluminum (Al) is also lower than 1,000° C. In the present embodiment, a description is given on the assumption that the second metal is an aluminum-copper alloy.

The seed layer c serves as an electrode used when metal is deposited by use of an electrolytic plating method. Further, the seed layer c also plays a role of a seed layer for the metal to be deposited by an electrolytic plating method. The material of the seed layer c may be selected depending on the type of metal to be deposited on the seed layer c. More specifically, the second portion b is deposited on the exposed surface of the seed layer c, and hence, it is sufficient that the seed layer c includes a material that can serve as a seed for the material of the second portion b.

In the present embodiment, since the second metal is an aluminum-copper alloy, the material of the seed layer c is a material that can serve as a seed for an aluminum-copper alloy. For example, the seed layer c may include a metal such as an aluminum-copper alloy or copper. Here, an example in which the seed layer c includes an aluminum-copper alloy is described.

The barrier metal layer f contains, but is not limited to, a high melting point metal, for example. The barrier metal layer f includes a metal such as titanium (Ti), titanium nitride (TiN), or tantalum (Ta). The barrier metal layer f has functions such as ensuring adhesion between the connection pad A and the insulating film d and preventing the metal that constitutes the connection pad A from being diffused into the insulating film d.

### <<Method of Manufacturing Photodetector>>

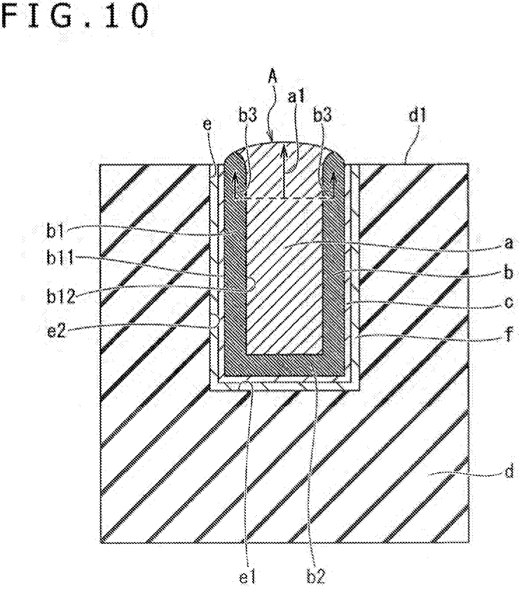

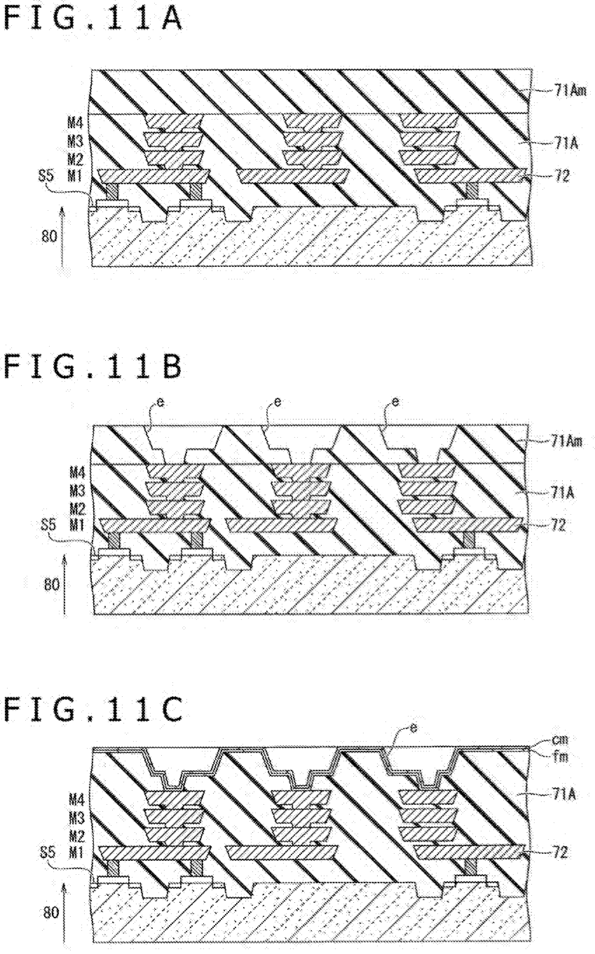

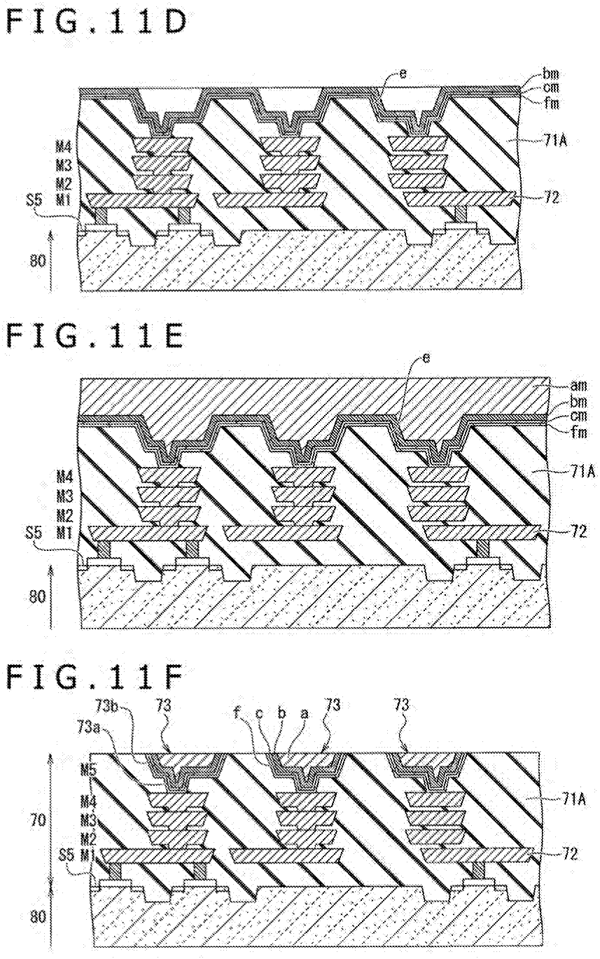

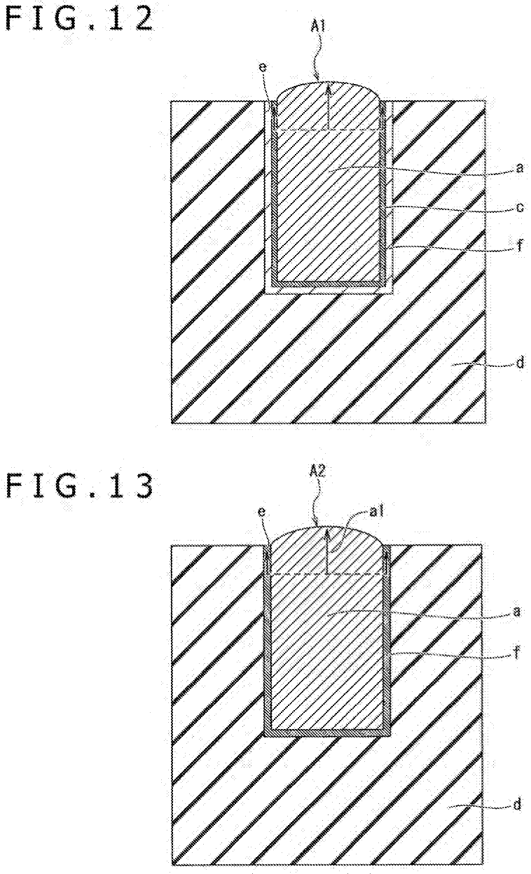

Now, with reference to FIG. 11A to FIG. 11F, a method of manufacturing the photodetector 1 is described. Note that, here, only a method of forming a connection pad is described. Besides, as an example of the method of forming a connection pad, a method of forming the fourth connection pad 73 is described.

As depicted in FIG. 11A, the layers up to the metal layer M4 are formed on the fifth surface S5 side of the third semiconductor layer 80. After that, an insulating film 71Am is stacked on the exposed surface of the wiring layer. The insulating film 71Am may have, but is not limited to, a stacked structure including, for example, a silicon oxide film, a silicon nitride film, and a silicon oxide film in this order. Then, as depicted in FIG. 11B, the opening e is formed in the insulating film 71Am by use of known lithography and etching techniques. Note that, from the next figure, the insulating film 71Am and the insulating film 71A are not distinguished, and they are simply referred to as the “insulating film 71A.”

Next, as depicted in FIG. 11C, a film fm that forms the barrier metal layer f and a film cm that forms the seed layer c are stacked on the exposed surface of the insulating film 71A in this order by use of known techniques such as sputtering. After that, metal is deposited by a plating method.

First, as depicted in FIG. 11D, at the initial stage of plating, a film bm including the second metal is deposited on the exposed surface of the film cm. Here, an aluminum-copper alloy is deposited as the second metal. After that, as depicted in FIG. 11E, a film am including the first metal is deposited on the exposed surface of the film bm by a plating method. Here, copper is deposited.

Then, as depicted in FIG. 11F, excess portions of the films fm, cm, bm, and am are removed by a CMP method. More specifically, the exposed surface of the wiring layer is polished by a CMP method to flatten the exposed surface and remove the portions of the films fm, cm, bm, and am other than the portions embedded in the opening e. With this, the fourth connection pad 73 belonging to a metal layer M5 is almost completed. Then, the third wiring layer 60 and the fourth wiring layer 70 are superposed and bonded together and subjected to heat treatment.

Note that, as depicted in FIG. 11F, the fourth connection pad 73 has, along the stacking direction from the third semiconductor layer 80 side, a body portion 73a and a head portion 73b connected to the end portion on the opposite side to the third semiconductor layer 80 side of the body portion 73a and wider than the body portion 73a. Among the body portion 73a and the head portion 73b, the head portion 73b which has a greater volume than the body portion 73a exhibits a greater amount of expansion during heat treatment. Further, the head portion 73b forms the surface of the fourth connection pad 73, and hence, a portion desired to expand more due to heat treatment to prevent the deterioration of contact characteristics between the connection pads is mainly the portion forming the head portion 73b. Thus, it is sufficient that the sidewall portion b1 of the second portion b is formed on at least the sidewall of the head portion 73b among the sidewall of the body portion 73a and the sidewall of the head portion 73b.

Note that, to the third connection pad 63 that is bonded with the fourth connection pad 73 as described above, the configuration of the connection pad A may be applied as needed. For example, if bonding characteristics between the third connection pad 63 and the fourth connection pad 73 are achieved, the configuration of the connection pad A may not be applied to the third connection pad 63. Further, to achieve bonding characteristics between the third connection pad 63 and the fourth connection pad 73, it is desirable to apply the configuration of the connection pad A to the third connection pad 63 in some cases.

### Main Effect of Second Embodiment

Hitherto, the deterioration of contact characteristics between connection pads has been prevented by performing heat treatment on the connection pads after superposing the connection pads on each other, thereby expanding the metal that constitutes the connection pads. Further, there has been a risk that, when connection pads are formed by use of a CMP method, the metal that constitutes the connection pads is ground more than the insulating films to retract, resulting in recesses. In a case where recesses are generated, to prevent the deterioration of contact characteristics between the connection pads, it has been necessary to expand the metal that constitutes the connection pads by heat treatment, thereby compensating for the volume of the recesses with the amount of expansion.

Meanwhile, along with the miniaturization of elements, a reduction in the dimensions of connection pads is desired. Reducing the dimensions of connection pads also reduces their volume. As the volume of connection pads is reduced, the amount of expansion during heat treatment is also reduced. The amount of expansion of metal due to heat is determined depending on the volume and expansion rate of the metal. While the expansion rate remains constant, a reduction in volume leads to a reduction in the amount of expansion.

Further, the amount of deformation due to heat of a barrier metal layer provided between the connection pad and the insulating film is small. Thus, there have been cases where, even though the metal that constitutes a connection pad is to expand during heat treatment, the surface in contact with the barrier metal layer of the metal that constitutes the connection pad is restrained by the barrier metal layer, thereby preventing the metal that constitutes the connection pad from expanding. The influence of such restraint by a barrier metal layer on the amount of expansion has increased along with a reduction in the dimensions of connection pads.

In a case where heat treatment is performed, a portion around the central portion of a connection pad in plan view generally expands more easily. This is because the portion around the central portion is farther from the barrier metal layer than the peripheral portions and less likely to be restrained. If the dimensions of a connection pad in plan view are reduced, as the dimensions are reduced, the distance between the central portion of the connection pad in plan view and the barrier metal layer is also reduced. Thus, as the dimensions of a connection pad in plan view are reduced, the central portion in plan view is more likely to be restrained by the barrier metal layer. In this way, there have been cases where the intended amount of expansion is not achieved due to inhibition by the barrier metal layer. Thus, to ensure the amount of expansion, the dimensions of connection pads have sometimes been increased in the stacking direction. However, increasing connection pads in size in the stacking direction has increased the volume of the connection pads, leading to an increase in the dimensions in the stacking direction of the semiconductor chips.

In contrast to this, in the photodetector 1 according to the second embodiment of the present technology, at least one of a pair of connection pads has the first portion “a” which includes the first metal and forms the surface of the connection pad in question, and the second portion b which is provided between the first portion “a” and the insulating film and includes the second metal that is more easily plastically deformed than the first metal. With this, even when the surface b11 of the second portion b is restrained by the barrier metal layer f during heat treatment, the second metal that constitutes the second portion b can be plastically deformed to absorb the restraint by the barrier metal layer f. Thus, the restraint by the barrier metal layer f is less likely to transmit to the first portion “a,” thereby making it possible to prevent the amount of expansion of the first portion “a” from being influenced by the barrier metal layer f. As a result, even in a case where the dimensions of the connection pads in plan view are reduced, the deterioration of contact characteristics between the connection pads can be prevented.

As a result of simulations of the thermal expansion of the metal that constitutes the connection pads, it has been found that the amount of thermal expansion is improved by approximately 33% in a case where the second portion b including the second metal is provided compared to a case where the second portion b is not provided.

Further, in the photodetector 1 according to the second embodiment of the present technology, since the inhibition of the expansion of the metal that constitutes the connection pads by the barrier metal layer can be prevented, the deterioration of contact characteristics between the connection pads can be prevented without changing the volume of the connection pads. Thus, there is no need to increase the dimensions along the stacking direction of the connection pads to increase the volume of the connection pads. With this, an increase in the thickness in the stacking direction of the semiconductor chip 2 can be prevented.

Further, even with the photodetector 1 according to the second embodiment, similar effects to the above-mentioned photodetector 1 according to the first embodiment can be obtained.

### First Modified Example of Second Embodiment

A first modified example of the second embodiment of the present technology depicted in FIG. 12 is described below. The photodetector 1 according to the first modified example of the second embodiment is different from the above-mentioned photodetector 1 according to the second embodiment in that the seed layer c includes the second metal, while the configuration of the photodetector 1 other than that is basically similar to the configuration of the above-mentioned photodetector 1 of the second embodiment. Note that the components already described are denoted by the same reference signs, and the description thereof is omitted.

### <Connection Pad>

FIG. 12 is an explanatory diagram depicting the configuration of a connection pad. The connection pad depicted in FIG. 12 is here referred to as a “connection pad A1” for convenience. The configuration of the connection pad A1 can be applied to any of the first connection pad 33, the second connection pad 43, the third connection pad 63, and the fourth connection pad 73 depicted in FIG. 9. The configuration of the connection pad A1 is desirably applied to all the first connection pad 33, the second connection pad 43, the third connection pad 63, and the fourth connection pad 73, but the configuration may be applied to at least one of these connection pads.

The connection pad A includes the first portion “a” and the seed layer c configured to function as a base for stacking the first portion “a” (first metal). In the first modified example of the second embodiment, the seed layer c functions as a second portion and a seed layer. The seed layer c is provided between the first portion “a” and the insulating film d. The seed layer c includes the second metal that is more easily plastically deformed than the first metal. Further, the first portion “a” is deposited on the seed layer c by a plating method. Thus, the seed layer c includes desirably a metal that also plays a role of a seed layer for the first metal that constitutes the first portion “a,” among the examples of the second metal described above.

### Main Effect of First Modified Example of Second Embodiment

Even with this photodetector 1 according to the first modified example of the second embodiment, similar effects to the above-mentioned photodetector 1 according to the second embodiment can be obtained.

### Second Modified Example of Second Embodiment

A second modified example of the second embodiment of the present technology depicted in FIG. 13 is described below. The photodetector 1 according to the second modified example of the second embodiment is different from the above-mentioned photodetector 1 according to the second embodiment in that the barrier metal layer f includes the second metal, while the configuration of the photodetector 1 other than that is basically similar to the configuration of the above-mentioned photodetector 1 of the second embodiment. Note that the components already described are denoted by the same reference signs, and the description thereof is omitted.

### <Connection Pad>

FIG. 13 is an explanatory diagram depicting the configuration of a connection pad. The connection pad depicted in FIG. 13 is here referred to as a “connection pad A2” for convenience. The configuration of the connection pad A2 can be applied to any of the first connection pad 33, the second connection pad 43, the third connection pad 63, and the fourth connection pad 73 depicted in FIG. 9. The configuration of the connection pad A2 is desirably applied to all the first connection pad 33, the second connection pad 43, the third connection pad 63, and the fourth connection pad 73, but the configuration may be applied to at least one of these connection pads.

The connection pad A includes the first portion “a” and the barrier metal layer f. In the second modified example of the second embodiment, the barrier metal layer f is also included in the connection pad A. Besides, the barrier metal layer f functions as a second portion. The barrier metal layer f is provided between the first portion “a” and the insulating film d. The barrier metal layer f includes the second metal that is more easily plastically deformed than the first metal. Further, the barrier metal layer f has functions such as ensuring adhesion between the first portion “a” and the insulating film d and preventing the metal that makes up the first portion “a” from being diffused into the insulating film d. Thus, the barrier metal layer f includes desirably a metal that has the functions described above, among the examples of the second metal.

### Main Effect of Second Modified Example of Second Embodiment

Even with this photodetector 1 according to the second modified example of the second embodiment, similar effects to the above-mentioned photodetector 1 according to the second embodiment can be obtained.

### Third Embodiment

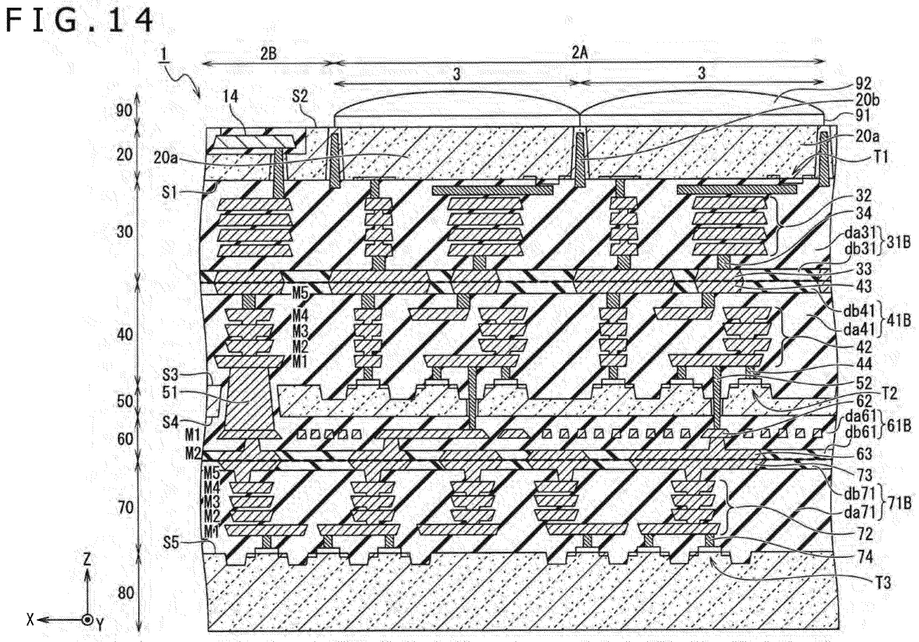

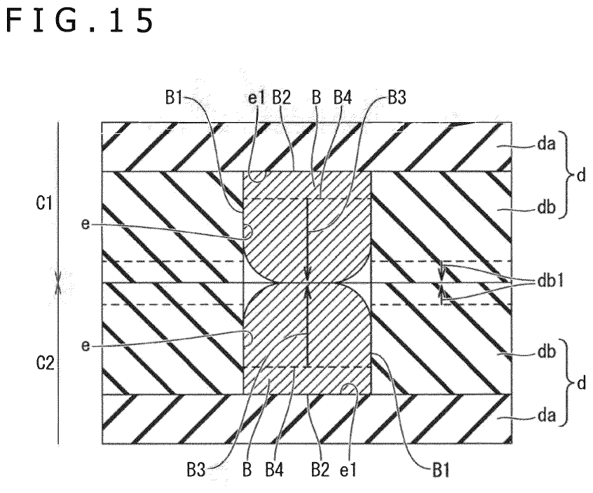

A third embodiment of the present technology depicted in FIG. 14 and FIG. 15 is described below. The photodetector 1 according to the third embodiment is different from the above-mentioned photodetector 1 according to the first embodiment in the insulating films of the wiring layers, while the configuration of the photodetector 1 other than that is basically similar to the configuration of the above-mentioned photodetector 1 of the first embodiment. Note that the components already described are denoted by the same reference signs, and the description thereof is omitted.

### <Insulating Film>

As depicted in FIG. 14, the first wiring layer 30 includes an insulating film 31B, the second wiring layer 40 includes an insulating film 41B, the third wiring layer 60 includes an insulating film 61B, and the fourth wiring layer 70 includes an insulating film 71B. The insulating film 31B includes an insulating film da31 and an insulating film db31, the insulating film 41B includes an insulating film da41 and an insulating film db41, the insulating film 61B includes an insulating film da61 and an insulating film db61, and the insulating film 71B includes an insulating film da71 and an insulating film db71. When there is no need to distinguish between the insulating film da31, the insulating film da41, the insulating film da61, and the insulating film da71, they are not distinguished from one another and are simply referred to as an “insulating film da.” When there is no need to distinguish between the insulating film db31, the insulating film db41, the insulating film db61, and the insulating film db71, they are not distinguished from one another and are simply referred to as an “insulating film db.”

### <Third Portion and Fourth Portion>

FIG. 15 is an explanatory diagram depicting the configuration of an insulating film around a connection pad. As depicted in FIG. 15, a wiring layer C1 is superposed and bonded with a wiring layer C2. The wiring layer C1 and the wiring layer C2 include respective connection pads B provided in the insulating film d and the insulating film d. The wiring layer C1 and the wiring layer C2 are electrically coupled to each other with the surfaces of the connection pads B bonded together. The connection pad B may have, but is not limited to, a configuration similar to that of the connection pad of the first embodiment, for example.

The insulating film d has a stacked structure of the insulating film da and the insulating film db. The insulating film da and the insulating film db are stacked in this order. The connection pad B is provided in the opening e formed in the insulating film d. The portion of the insulating film d adjacent to a side surface B1 of the connection pad B is referred to as a “third portion” in order to distinguish the portion from the other portions, and the portion of the insulating film d adjacent to a bottom surface B2 of the connection pad B is referred to as a “fourth portion” in order to distinguish the portion from the other portions. Besides, the linear expansion coefficient of the material of the third portion is smaller than the linear expansion coefficient of the material of the fourth portion. In the example depicted in FIG. 15, among the insulating film da and the insulating film db, the insulating film db is the third portion, and the insulating film da is the fourth portion. Note that the configurations of the third and fourth portions are desirably applied to all the insulating film 31B, the insulating film 41B, the insulating film 61B, and the insulating film 71B as depicted in FIG. 14, but the configurations may be applied to any of the connection pads of those insulating films. The configurations of the third and fourth portions may be applied to at least one of these connection pads.

When the wiring layer C1 is bonded with the wiring layer C2, first, the wiring layer C1 is superposed on the wiring layer C2, and after that, heat treatment is performed. The connection pads B expand when subjected to heat treatment, and the surfaces of the connection pads B are bonded together. The arrow B3 schematically indicates the amount of expansion of the connection pad B due to heat treatment. The amount of expansion of the connection pad B indicated by the arrow B3 is preferably greater. Note that a dashed line B4 of FIG. 15 indicates the position of the surface of the connection pad B before heat treatment. Further, when the wiring layer C1 and the wiring layer C2 are subjected to heat treatment, the insulating film d also expands. An arrow db1 schematically indicates the amount of expansion of the insulating film db due to heat treatment.

The greater the amount of expansion of the connection pad B, the more effectively the deterioration of contact characteristics between the connection pads can be prevented. Further, the smaller the amount of expansion of the insulating film db, the more effectively the deterioration of contact characteristics between the connection pads can be prevented. This is because the amount of expansion of the connection pad B substantially decreases due to the amount of expansion of the insulating film db. Thus, the difference (linear expansion coefficient difference) between the linear expansion coefficient of the material of the connection pad B and the linear expansion coefficient of the material of the insulating film db is desirably greater. In the present embodiment, to increase such a linear expansion coefficient difference, the material of the insulating film db is devised. As the material of the insulating film db, it is preferable to use a material with a smaller linear expansion coefficient.

Note that, regarding the material of the insulating film da, since the insulating film da is stacked on the connection pad B along the stacking direction, the amount of expansion of the connection pad B does not substantially decrease depending on the magnitude of the linear expansion coefficient of the insulating film da. Thus, among the insulating film da and the insulating film db, the insulating film db includes a material with a smaller linear expansion coefficient.

Examples of the material of the insulating film db include glass ceramics with a linear expansion coefficient adjusted by additives. Examples of additives include, but are not limited to, materials that contract when the temperature rises. Here, a description is given on the assumption that the material of the insulating film db is such a glass ceramic. The insulating film da may include a layer including, for example, silicon oxide.

### <<Method of Manufacturing Photodetector>>

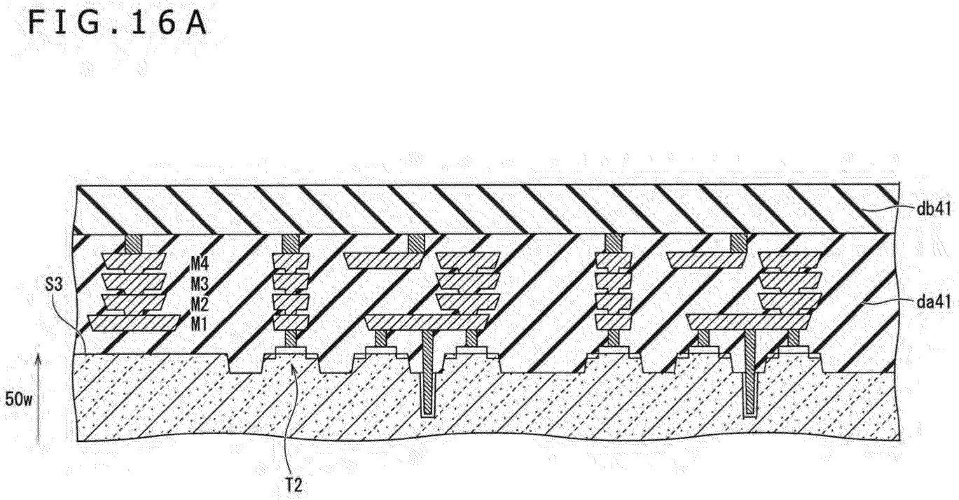

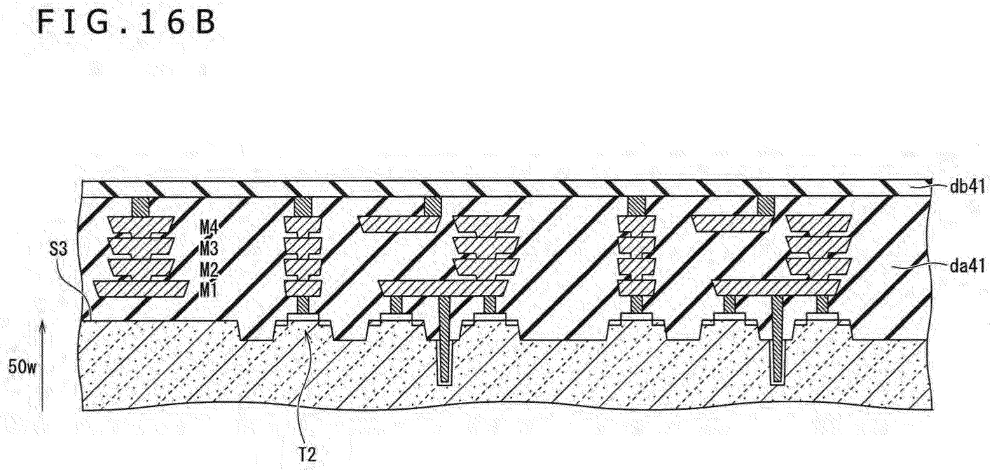

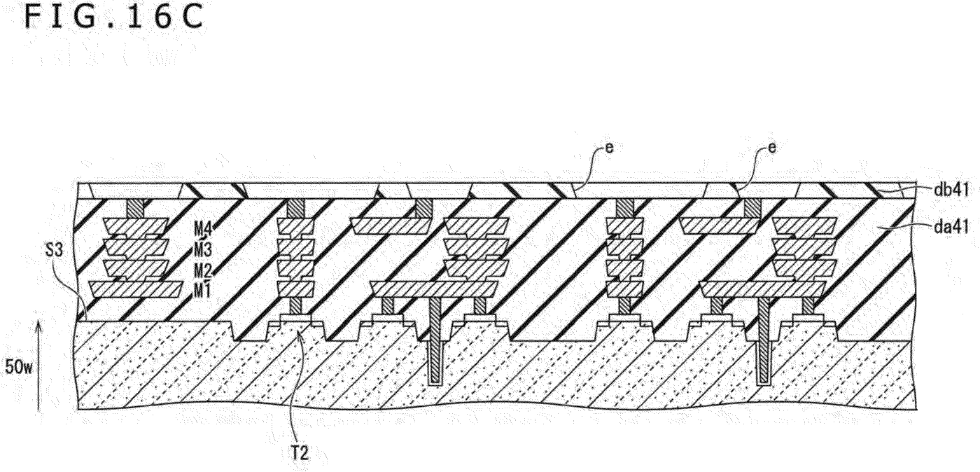

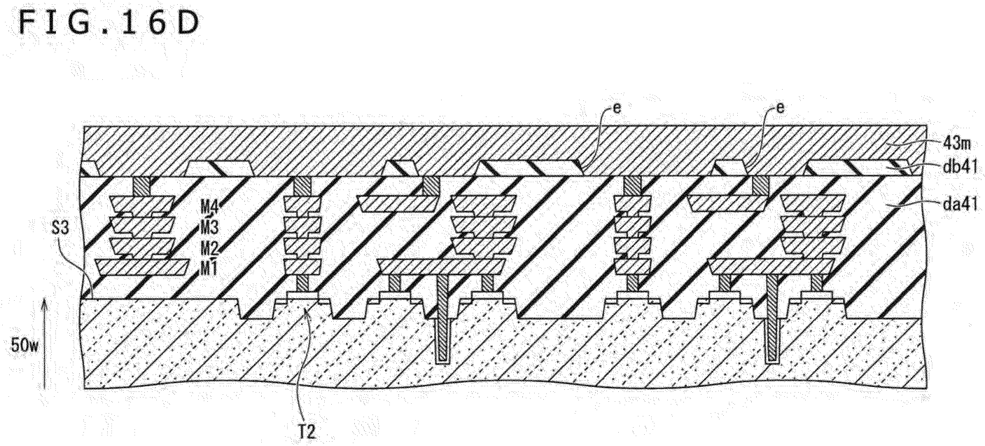

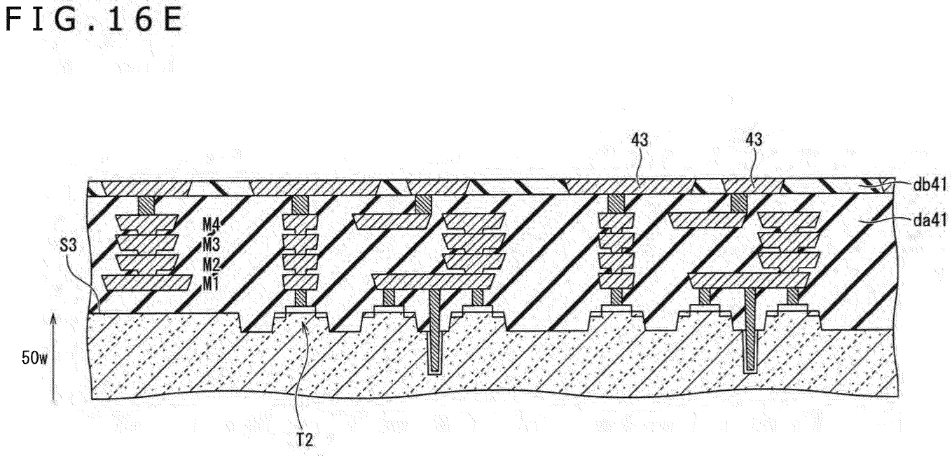

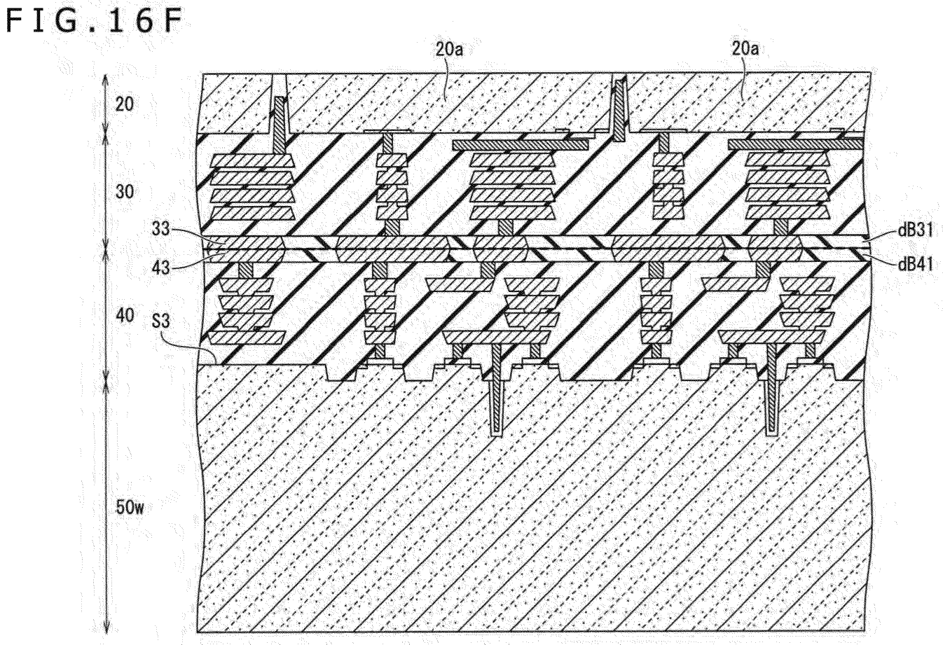

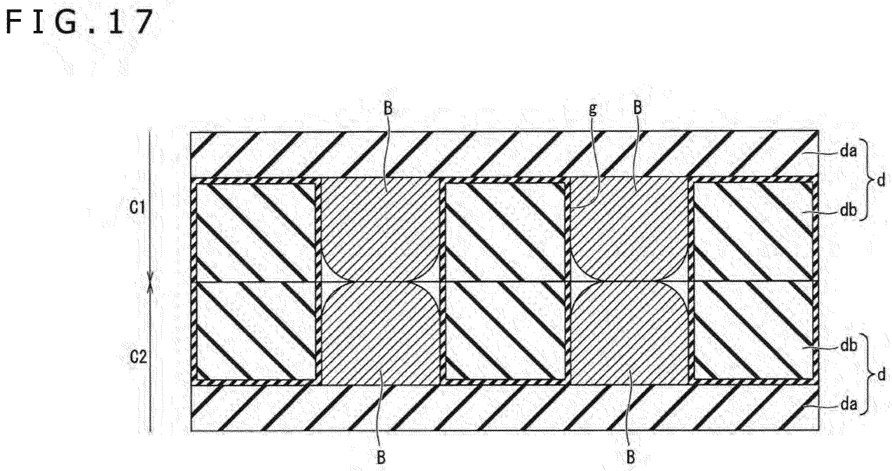

Now, with reference to FIG. 16A to FIG. 16F, a method of manufacturing the photodetector 1 is described. Note that, here, only a method of forming a connection pad is described. Besides, as an example of the method of forming a connection pad, a method of forming the second connection pad 43 is described.

As depicted in FIG. 16A, the layers up to the metal layer M4 are formed on the third surface S3 side of the second semiconductor layer 50w. The portion of the insulating film da41 exposed on the exposed surface of the wiring layer includes, for example, a silicon oxide film. After that, the glass ceramic db41 is stacked on the exposed surface of the wiring layer. More specifically, the plate-shaped glass ceramic db41 of an equivalent size to the second semiconductor layer 50w is prepared, and the prepared glass ceramic db41 is attached to the exposed surface of the wiring layer. Then, as depicted in FIG. 16B, back grinding or the like is performed on the exposed surface of the glass ceramic db41 to reduce the thickness of the glass ceramic db41.

Next, as depicted in FIG. 16C, the glass ceramic db41 is etched by use of known lithography and etching techniques to form the opening e. After that, the resist pattern is removed. Then, as depicted in FIG. 16D, a film 43m including copper is deposited on the exposed surface of the wiring layer to fill the opening e. More specifically, first, copper is deposited by use of known techniques such as sputtering, and after that, copper is deposited by a plating method. After that, as depicted in FIG. 16E, excess portions of the film 43m are removed by a CMP method to obtain the second connection pad 43. Then, as depicted in FIG. 16F, the second wiring layer 40 and the first wiring layer 30 are superposed on each other and subjected to heat treatment. In the example depicted in FIG. 16F, the insulating film 31 of the first wiring layer 30 also includes the glass ceramic db31, like the second wiring layer 40.

### Main Effect of Third Embodiment

A case where, as the material of the insulating film db, silicon oxide which has hitherto been frequently used is used is considered. Since the linear expansion coefficient of copper is 16.5 ppm/K, while the linear expansion coefficient of silicon oxide is 0.6 ppm/K, the linear expansion coefficient difference between copper and silicon oxide is 15.9 ppm/K. As the dimensions of connection pads are reduced along with the miniaturization of elements, to compensate for recesses generated by retraction of the metal that constitutes the connection pads, the amount of expansion of the metal becomes more important.

A case where, as the material of the insulating film db (third portion), for example, ZERODUR (registered trademark) manufactured by SCHOTT AG is used is considered. ZERODUR (registered trademark) is a glass ceramic with a linear expansion coefficient of 0.02 ppm/K. Thus, the linear expansion coefficient difference between ZERODUR and copper is 16.48 ppm/K. In this way, the linear expansion coefficient can be greater than that in the case of forming the insulating film db with silicon oxide.

In this way, in the photodetector 1 according to the third embodiment of the present technology, a material with a smaller linear expansion coefficient is used as the material of the insulating film db, thereby making it possible to prevent the amount of expansion of the connection pads from substantially decreasing due to the amount of expansion of the insulating film db. Thus, insufficient bonding characteristics between the connection pads can be prevented.

Further, in the photodetector 1 according to the third embodiment of the present technology, the linear expansion coefficient of the material of the third portion which is a portion adjacent to the side surface of the connection pad is smaller than the linear expansion coefficient of the material of the fourth portion which is a portion adjacent to the bottom surface of the connection pad. Among the insulating film da and the insulating film db, the insulating film db which influences the substantial expansion amount of the connection pads, includes selectively a material with a smaller linear expansion coefficient. Consequently, insufficient bonding characteristics between the connection pads can be prevented.

Further, even with the photodetector 1 according to the third embodiment, similar effects to the above-mentioned photodetector 1 according to the first embodiment can be obtained.

### First Modified Example of Third Embodiment

A first modified example of the third embodiment of the present technology depicted in FIG. 17 is described below. The photodetector 1 according to the first modified example of the third embodiment is different from the above-mentioned photodetector 1 according to the third embodiment in including a contact layer, while the configuration of the photodetector 1 other than that is basically similar to the configuration of the above-mentioned photodetector 1 of the first embodiment. Note that the components already described are denoted by the same reference signs, and the description thereof is omitted.

### <Contact Layer>

FIG. 17 is an explanatory diagram depicting the configuration of a contact layer g. The contact layer g is provided between the insulating film db which is the third portion, and the insulating film da. More specifically, the insulating film db which is the third portion, is bonded with the insulating film da through the contact layer g. Further, the contact layer g is also provided between the insulating film db and the connection pad B. The contact layer g includes at least one of a silicon oxide film, a silicon nitride film, a silicon carbonitride (SiCN) film, a carbon-containing silicon oxide film, a silicon carbide (SiC) film, an aluminum oxide film (Al₂O₃), and a tantalum oxide film (Ta₂O₃).

### <<Method of Manufacturing Photodetector>>

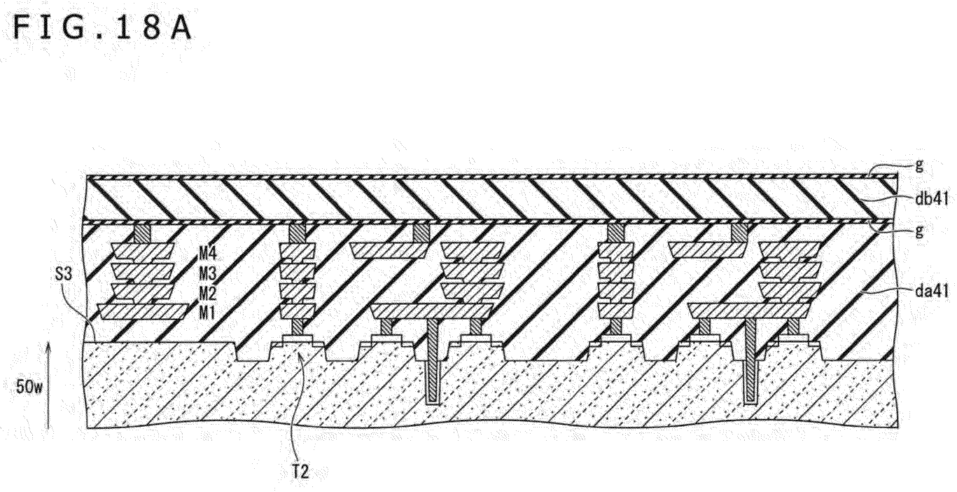

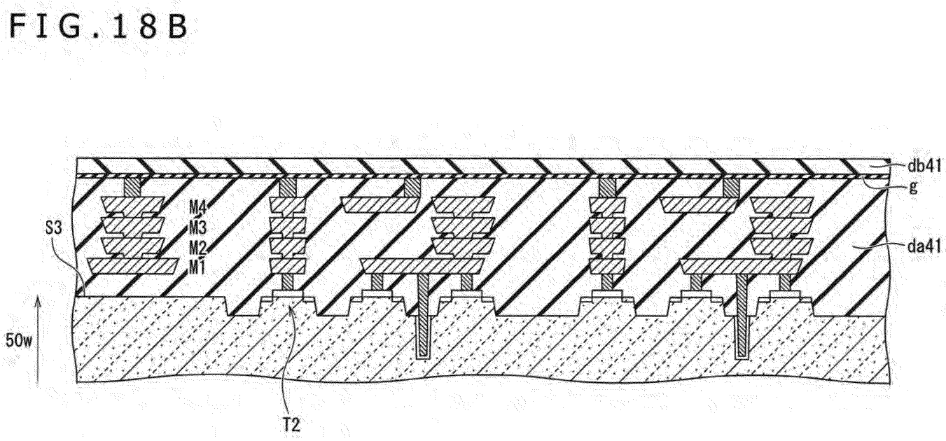

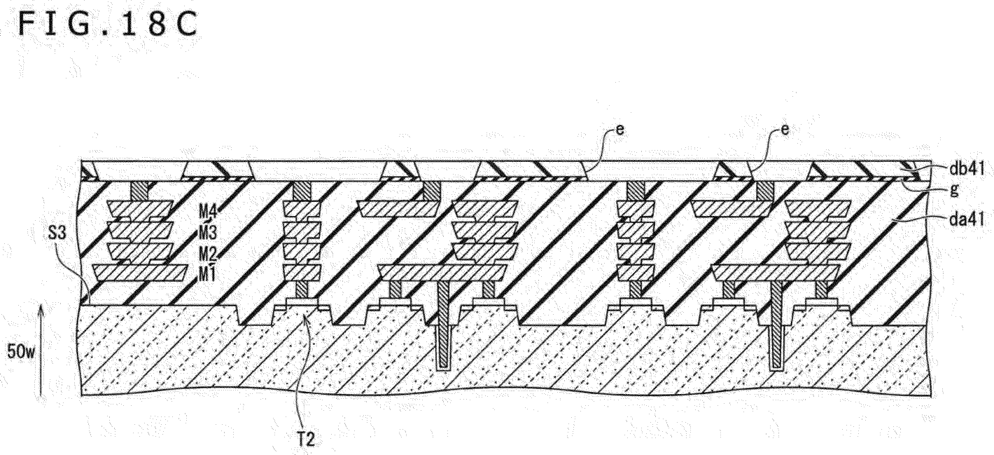

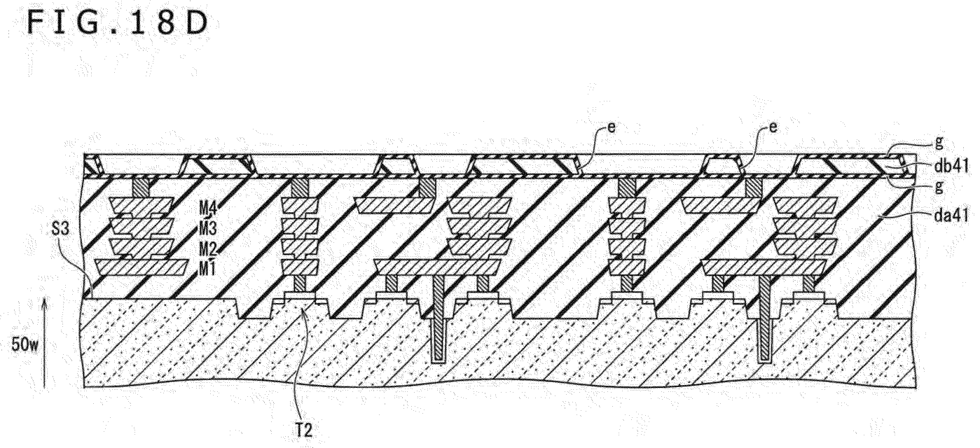

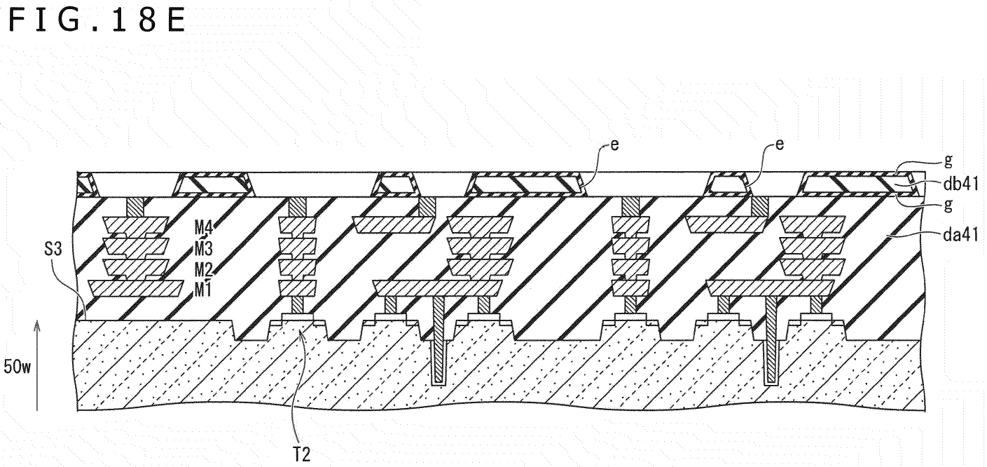

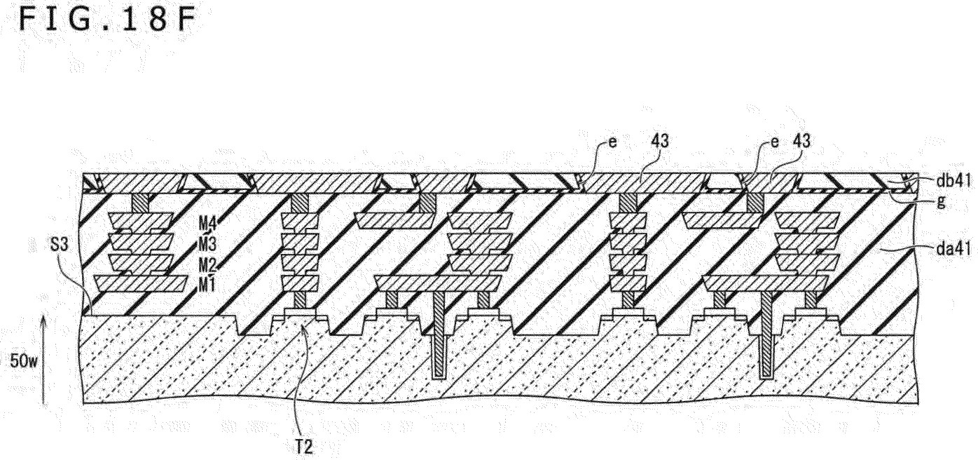

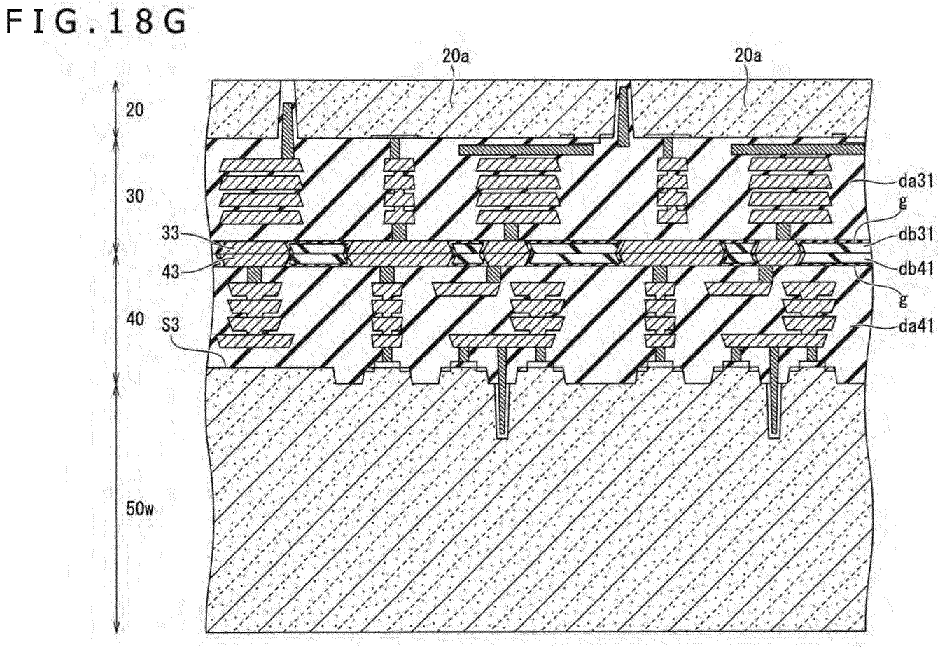

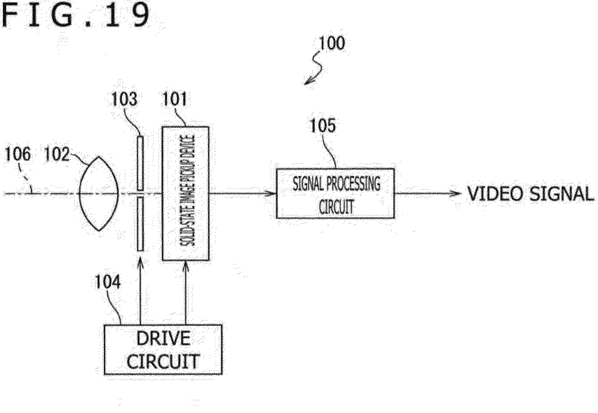

Now, with reference to FIG. 18A to FIG. 18G, a method of manufacturing the photodetector 1 is described. Note that, here, only a method of forming a connection pad is described. Besides, as an example of the method of forming a connection pad, a method of forming the second connection pad 43 is described.

As depicted in FIG. 18A, the layers up to the metal layer M4 are formed on the third surface S3 side of the second semiconductor layer 50w. The portion of the insulating film da41 exposed on the exposed surface of the wiring layer includes, for example, a silicon oxide film. After that, the glass ceramic db41 with the contact layers g on both the surfaces thereof is stacked on the exposed surface of the wiring layer (for example, insulating film da41 and the like). More specifically, the plate-shaped glass ceramic db41 of an equivalent size to the second semiconductor layer 50w which has the contact layers g deposited on both the surfaces thereof is prepared, and the prepared glass ceramic db41 is attached to the exposed surface of the wiring layer. Then, as depicted in FIG. 18B, back grinding or the like is performed on the exposed surface to reduce the thickness of the glass ceramic db41.

Next, as depicted in FIG. 18C, the glass ceramic db41 and the contact layer g are etched by use of known lithography and etching techniques to form the opening e. After that, the resist pattern is removed. Then, as depicted in FIG. 18D, the contact layer g is deposited on the exposed surface. Subsequently, as depicted in FIG. 18E, the portion of the contact layer g stacked on the bottom surface of the opening e is removed by use of known lithography and etching techniques. Hence, the portion of the contact layer g deposited on the exposed surface of the glass ceramic db41 is left. More specifically, the portion of the contact layer g stacked on the side surface of the opening e and the portion of the contact layer g stacked on the surface of the glass ceramic db41 on the opposite side to the second semiconductor layer 50 side are left. After that, the resist pattern is removed.

Next, as depicted in FIG. 18F, a film including copper is deposited on the exposed surface of the wiring layer to fill the opening e. Then, excess portions of the film including copper are removed by a CMP method. Accordingly, the second connection pad 43 is obtained. Further, through this CMP process, the portion of the contact layer g stacked on the surface of the glass ceramic db41 on the opposite side to the second semiconductor layer 50 side is also removed. With this, the glass ceramic db41 is exposed.

Then, as depicted in FIG. 18G, the second wiring layer 40 and the first wiring layer 30 are superposed on each other and subjected to heat treatment. In the example depicted in FIG. 18G, the insulating film 31 of the first wiring layer 30 also includes the glass ceramic db41 and the contact layer g, like the second wiring layer 40. Then, the exposed surfaces of the glass ceramics db41 are bonded together to bond the first connection pad 33 with the second connection pad 43.

### Main Effect of First Modified Example of Third Embodiment

Even with this photodetector 1 according to the first modified example of the third embodiment, similar effects to the above-mentioned photodetector 1 according to the third embodiment can be obtained.

Moreover, in this photodetector 1 according to the first modified example of the third embodiment, since the contact layer g is stacked on the portion of the glass ceramic db that is bonded with the wiring layer, bonding characteristics between the layers forming the wiring layers can be at least bonding characteristics similar to conventional ones.

Further, since the contact layers g are provided between the glass ceramic db and the insulating film da and between the glass ceramic db and the wiring lines such as the second connection pad 43, the material of the glass ceramic db can be prevented from being diffused into the surrounding area.

Note that, in the first modified example of the third embodiment, the contact layers g are deposited on both the surfaces of the glass ceramic db41. However, the contact layer g may be deposited only on the surface of the glass ceramic db41 on the side that is bonded to the wiring layer.

### Second Modified Example of Third Embodiment

A second modified example of the third embodiment of the present technology is described below. The photodetector 1 according to the second modified example of the third embodiment is different from the above-mentioned photodetector 1 according to the third embodiment in the material of the third portion (insulating film db), while the configuration of the photodetector 1 other than that is basically similar to the configuration of the above-mentioned photodetector 1 of the third embodiment. Note that the components already described are denoted by the same reference signs, and the description thereof is omitted. Further, here, FIG. 14 and FIG. 15 are reused for description.

### <Third Portion>

The linear expansion coefficient of the material of the third portion (insulating film db) is smaller than the linear expansion coefficient of the material of the fourth portion (insulating film da). More specifically, the linear expansion coefficient of the material of the insulating film db is a negative value. Substances generally expand when heated, but materials with a negative linear expansion coefficient have the property of contracting when heated. The insulating film db is made of a material with a negative linear expansion coefficient or contains a material with a negative linear expansion coefficient. Examples of materials with a negative linear expansion coefficient include cubic zirconium tungstate, copper (Cu)-zinc (Zn)-vanadium (V) oxides (Cu—Zn—V—O-based oxides), zirconium phosphate, zirconium phosphate tungstate, and fillers including glasses with a negative linear expansion coefficient.

Cubic zirconium tungstate continuously contracts as the temperature rises in the temperature range from 0.3 K to the thermal decomposition point of 1050 K. As materials that exhibit similar behavior, compounds with the composition formula AM₂O₈ (A=zirconium (Zr) or hafnium (Hf) and M=molybdenum (Mo) or tungsten (W)), zirconium pyrovanadate (ZrV₂O₇), and the like can be given. Further, compounds with the composition formula A₂(MO₄)₃ (A=zirconium (Zr) or hafnium (Hf) and M=molybdenum (Mo) or tungsten (W)) also exhibit controllable negative thermal expansion.

Cu—Zn—V—O-based oxides are oxides including three metals, namely, copper, zinc, and vanadium. Examples of Cu—Zn—V—O-based oxides include CG-NiTE (registered trademark) manufactured by IBLC Co., Ltd. The linear expansion coefficient of CG-NiTE (registered trademark) is approximately −10 ppm/K to approximately −5 ppm/K. Cu—Zn—V—O-based oxides may also be in the form of particles, and in such a case, the Cu—Zn—V—O-based oxides may be added to materials such as glass or resin to be used.

The linear expansion coefficient of zirconium phosphate is approximately −2, and the linear expansion coefficient of zirconium phosphate tungstate is approximately −3.

Examples of fillers including glasses with a negative linear expansion coefficient include fillers including low thermal expansion glass-ceramics manufactured by Nippon Electric Glass Co., Ltd. The linear expansion coefficient of fillers including low thermal expansion glass-ceramics manufactured by Nippon Electric Glass Co., Ltd. is, for example, approximately-1.1 ppm/K to approximately-0.9 ppm/K. Since fillers are in the form of particles, the fillers may be added to materials such as glass or resin to be used.

### Main Effect of Second Modified Example of Third Embodiment

Even with this photodetector 1 according to the second modified example of the third embodiment, similar effects to the above-mentioned photodetector 1 according to the third embodiment can be obtained.

In this photodetector 1 according to the second modified example of the third embodiment, a case where, as the material of the insulating film db (third portion), for example, zirconium phosphate is used is considered. The linear expansion coefficient of zirconium phosphate is −2 ppm/K. Thus, the linear expansion coefficient difference between zirconium phosphate and copper which has a linear expansion coefficient of 16.5 ppm/K is 18.5 ppm/K. In this way, the linear expansion coefficient can be greater than that in the case of forming the insulating film db with silicon oxide as described in the third embodiment. Moreover, since the linear expansion coefficient of zirconium phosphate is negative, the linear expansion coefficient difference can be greater than the value of the linear expansion coefficient of copper which is 16.5 ppm/K. Thus, the substantial linear expansion coefficient of the metal that constitutes the connection pads, such as copper, can be greater than the original value of the material. In other words, the substantial expansion coefficient can be increased without changing the metal that constitutes the connection pads. Thus, insufficient bonding characteristics between the connection pads can be prevented.

Note that the materials with a negative linear expansion coefficient described above may be used as the material of the insulating film db (third portion) in the photodetector 1 according to the first modified example of the third embodiment depicted in FIG. 17 and the like.

### Fourth Embodiment

### <Application Example to Electronic Apparatus>

Next, an electronic apparatus 100 according to a fourth embodiment of the present technology depicted in FIG. 19 is described. The electronic apparatus 100 includes a solid-state image pickup device 101, the optical lens 102, a shutter device 103, a drive circuit 104, and a signal processing circuit 105. The electronic apparatus 100 is, but is not limited to, an electronic apparatus such as a camera. Further, the electronic apparatus 100 includes the above-mentioned photodetector 1 as the solid-state image pickup device 101.

The optical lens (optical system) 102 forms an image of image light (incident light 106) from an object on the image pickup surface of the solid-state image pickup device 101. Accordingly, signal charges are accumulated in the solid-state image pickup device 101 over a certain period. The shutter device 103 controls the periods of light irradiation and light blocking to the solid-state image pickup device 101. The drive circuit 104 supplies drive signals for controlling the transfer operation of the solid-state image pickup device 101 and the shutter operation of the shutter device 103. By drive signals (timing signals) supplied from the drive circuit 104, signals are transferred from the solid-state image pickup device 101. The signal processing circuit 105 performs various types of signal processing on signals (pixel signals) output from the solid-state image pickup device 101. Video signals subjected to signal processing are stored in a storage medium such as a memory or output to a monitor.

With such a configuration, since the electronic apparatus 100 includes the photodetector 1 with reduced power consumption and increased speed as the solid-state image pickup device 101, the electronic apparatus 100 can achieve a reduction in power consumption and a further increase in speed. Further, it is possible to prevent insufficient bonding characteristics between the connection pads of the solid-state image pickup device 101, thereby improving the reliability of the electronic apparatus 100.

Note that the electronic apparatus 100 is not limited to a camera and may be another electronic apparatus. For example, the electronic apparatus 100 may be an image pickup device such as a camera module for a mobile device such as a cell phone.

Further, the electronic apparatus 100 can include, as the solid-state image pickup device 101, the photodetector 1 according to any one of the first embodiment to the third embodiment and the modified examples thereof, or the photodetector 1 according to a combination of at least two of the first embodiment to the third embodiment and the modified examples thereof.

### <2. Application Example to Mobile Body>

The technology according to the present disclosure (present technology) can be applied to various products. For example, the technology according to the present disclosure may be implemented as a device that is mounted on any type of mobile body such as an automobile, an electric vehicle, a hybrid electric vehicle, a motorcycle, a bicycle, a personal mobility, an airplane, a drone, a ship, or a robot.

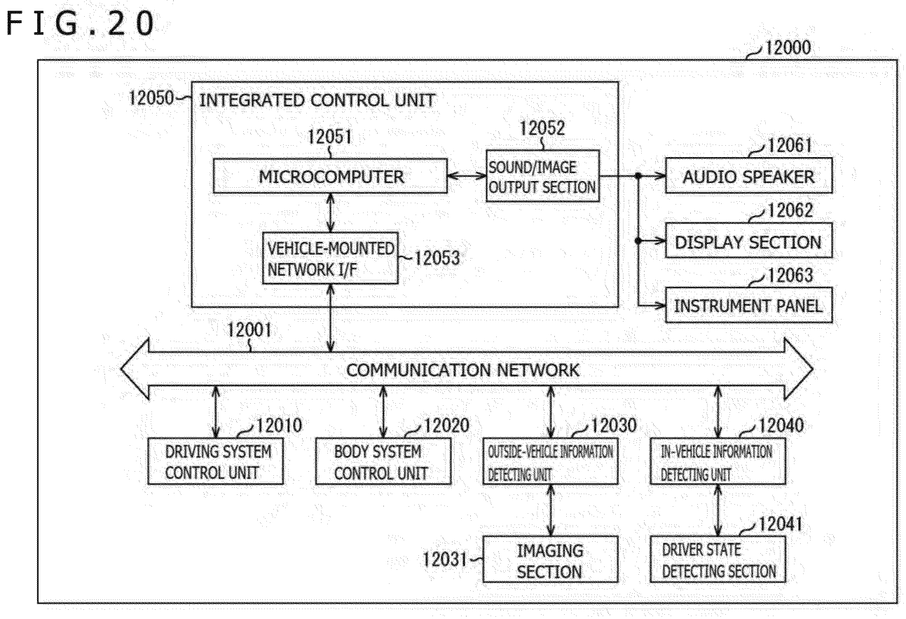

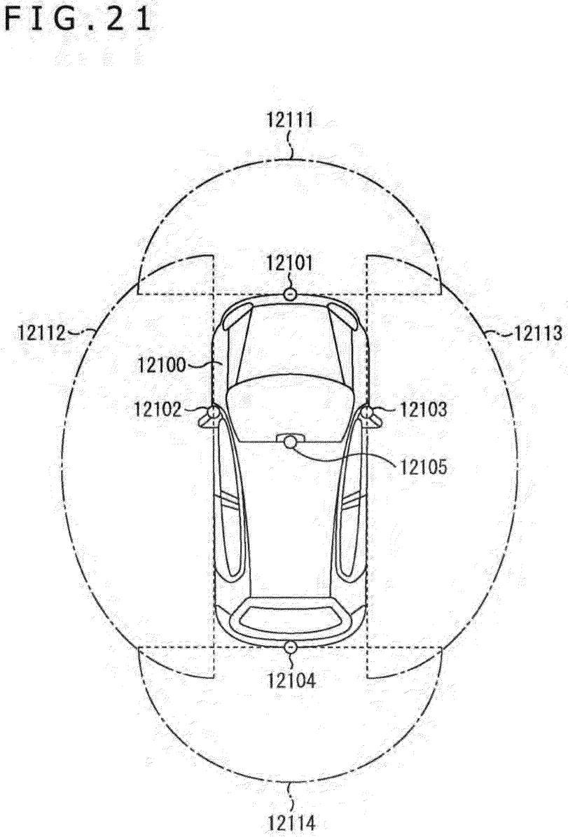

FIG. 20 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 20, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 20, an audio speaker 12061, a display section 12062, and an instrument panel 12063 are illustrated as the output device. The display section 12062 may, for example, include at least one of an on-board display and a head-up display.

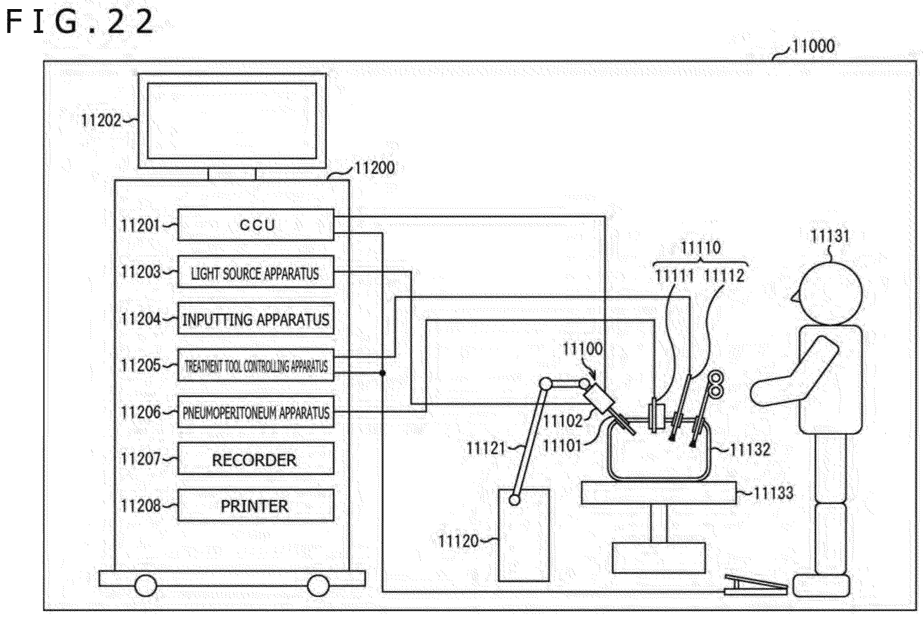

FIG. 21 is a diagram depicting an example of the installation position of the imaging section 12031.

In FIG. 21, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 21 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to the imaging section 12031 and the like among the configurations described above, for example. Specifically, the photodetector 1 described above can be applied to the imaging section 12031. The technology according to the present disclosure is applied to the imaging section 12031, thereby making it possible to prevent insufficient bonding characteristics between the connection pads of the imaging section 12031, so that the reliability of the imaging section 12031 can be improved.

### <3. Application Example to Endoscopic Surgery System>

The technology according to the present disclosure (present technology) can be applied to various products. For example, the technology according to the present disclosure may be applied to endoscopic surgery systems.

FIG. 22 is a view depicting an example of a schematic configuration of an endoscopic surgery system to which the technology according to an embodiment of the present disclosure (present technology) can be applied.

In FIG. 22, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

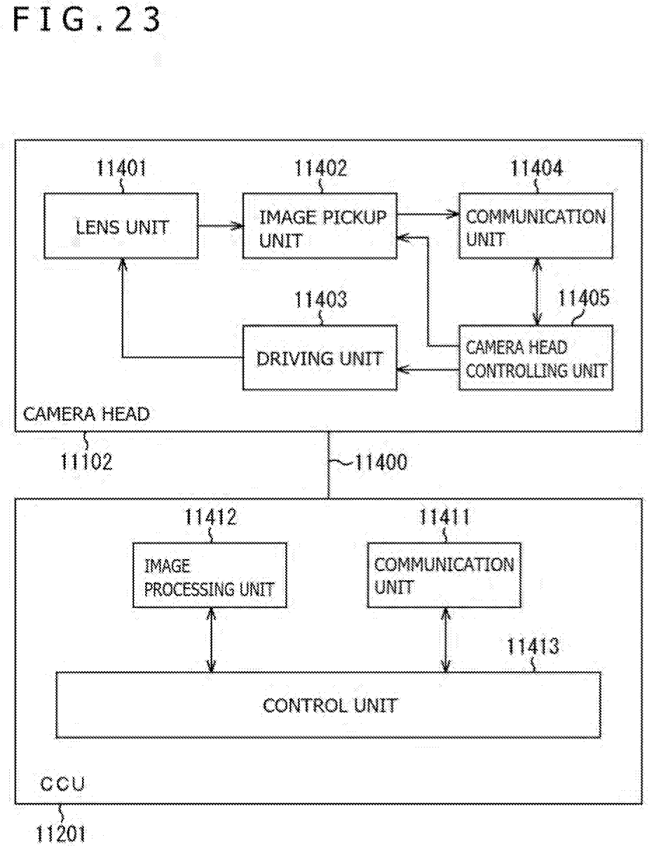

FIG. 23 is a block diagram depicting an example of a functional configuration of the camera head 11102 and the CCU 11201 depicted in FIG. 22.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of the endoscopic surgery system to which the technology according to the present disclosure can be applied has been described above. The technology according to the present disclosure can be applied to the image pickup unit 11402 of the camera head 11102 among the configurations described above, for example. Specifically, the photodetector 1 described above can be applied to the image pickup unit 11402. The technology according to the present disclosure is applied to the image pickup unit 11402, thereby making it possible to prevent insufficient bonding characteristics between the connection pads of the image pickup unit 11402, thereby improving the reliability of the image pickup unit 11402.

Note that, here, the endoscopic surgery system has been described as an example. However, the technology according to the present disclosure may also be applied to other systems such as microscope surgery systems.

### Other Embodiments

As described above, the present technology has been described by the plurality of embodiments, but it is to be understood that the present technology is not limited by the statements and drawings included in part of this disclosure. Various alternative embodiments, examples, and operational techniques may become apparent to those skilled in the art from this disclosure.

For example, the respective technical ideas described in the first embodiment to the third embodiment can also be combined with each other. For example, all the configuration of the pillar according to the first embodiment, the configuration of the connection pad according to the second embodiment, and the configuration of the insulating film db according to the third embodiment may be combined, or two of them can be combined. At least two of these embodiments are combined, thereby making it possible to prevent insufficient bonding characteristics between the connection pads more effectively.

Further, in the photodetector 1 according to the second embodiment, the insulating films 31A, 41A, 61A, and 71A may include the first material that is a low dielectric constant (Low-K) insulating material. In the photodetector 1 according to the second embodiment of the present technology, since the influence of the barrier metal layer f on the amount of expansion of the first portion “a” can be prevented, even when the insulating films include the first material, the deterioration of contact characteristics between the connection pads can be prevented. Moreover, the insulating films 31A, 41A, 61A, and 71A may each include at least partially the first material that is a low dielectric constant (Low-K) insulating material. Similarly, in the photodetector 1 according to the third embodiment, the insulating film da may include the first material that is a low dielectric constant (Low-K) insulating material. In the photodetector 1 according to the third embodiment of the present technology, since the amount of expansion of the insulating film db can be reduced, even when the insulating film da includes the first material, the deterioration of contact characteristics between the connection pads can be prevented. Moreover, the insulating film da of each wiring layer may include at least partially the first material that is a low dielectric constant (Low-K) insulating material. In this way, various combinations in accordance with the respective technical ideas are possible.

Moreover, the photodetector 1 described above includes three semiconductor layers, but the present technology is not limited to this, and it is sufficient that the photodetector 1 includes at least two semiconductor layers.

Further, the present technology can be applied to a wide range of photodetectors including not only solid-state image pickup devices, which serve as image sensors described above, but also ranging sensors configured to measure distances, which are also called “ToF (Time of Flight) sensor,” and the like. A ranging sensor emits irradiation light toward an object, detects reflected light that is the irradiation light reflected by the surface of the object to return, and calculates the distance to the object on the basis of the time of flight from the emission of irradiation light to the reception of the reflected light. The structure including the connection pads and the insulating films described above can be adopted as the structure of this ranging sensor. Further, the present technology can also be applied to semiconductor devices other than the photodetector 1.

In this way, the present technology includes various embodiments and the like not described here, as a matter of course. Thus, the technical scope of the present technology is defined only by the matters to define the invention described in CLAIMS supported by the above description.

Further, the effects described herein are merely illustrative and not limited, and other effects may be provided.

Note that the present technology may adopt the following configurations.

(1)

A photodetector including:
at least two semiconductor layers; and
a wiring layer on one side in a stacking direction and a wiring layer on another side in the stacking direction, the wiring layers being interposed between the semiconductor layers, each including an insulating film and a connection pad provided in the insulating film, and being electrically coupled to each other with surfaces of the connection pads bonded together,
in which the at least two semiconductor layers include a semiconductor layer with a photoelectric conversion region on a light incident surface side,
the insulating film includes a first insulating film and a second insulating film that includes a material with a higher rigidity than a material of the first insulating film and penetrates the first insulating film in the stacking direction, and
the second insulating film is provided between the connection pad and at least one of the semiconductor layers.
   (2)

The photodetector according to (1),
in which the second insulating film has a pillar-shaped portion that extends along the stacking direction, and
one end of the pillar-shaped portion in the stacking direction is in contact with the connection pad, and another end thereof is in contact with one of the semiconductor layers.
   (3)

The photodetector according to (2), in which the pillar-shaped portion is provided at a position that does not overlap with a wiring line formed in the insulating film in the stacking direction.

(4)

The photodetector according to (2) or (3), in which a plurality of the pillar-shaped portions is provided for one of the connection pads.

(5)

The photodetector according to any one of (1) to (4), in which a dielectric constant of the material of the first insulating film is lower than a dielectric constant of the material of the second insulating film.

(6)

The photodetector according to any one of (1) to (5), in which the material of the second insulating film includes silicon oxide, silicon nitride, or silicon oxide and silicon nitride.

(7)

A photodetector including:
at least two semiconductor layers; and
a wiring layer on one side in a stacking direction and a wiring layer on another side in the stacking direction, the wiring layers being interposed between the semiconductor layers, each including an insulating film and a connection pad provided in the insulating film, and being electrically coupled to each other with surfaces of the connection pads bonded together,
in which the at least two semiconductor layers include a semiconductor layer with a photoelectric conversion region on a light incident surface side, and
at least one of the connection pads has a first portion including a first metal and forming the surface of the at least one of the connection pads, and a second portion provided between the first portion and the insulating film and including a second metal that is more easily plastically deformed than the first metal.
   (8)

The photodetector according to (7), in which the second portion is provided between at least a side surface of the first portion and the insulating film.

(9)

The photodetector according to (7) or (8), in which a melting point of the second metal is lower than a melting point of the first metal.

(10)

The photodetector according to any one of (7) to (9), in which the second portion includes a seed layer configured to function as a base for stacking the first metal or a barrier metal layer configured to prevent the first metal from being diffused into the insulating film.

(11)

The photodetector according to any one of (7) to (10),
in which the first metal includes copper, and
the second metal includes aluminum, an aluminum-copper alloy, an aluminum-silicon alloy, cadmium, tin, tantalum, lead, a lead-copper alloy, antimony, ytterbium, calcium, silver, germanium, strontium, or cerium.
   (12)

A photodetector including:
at least two semiconductor layers; and
a wiring layer on one side in a stacking direction and a wiring layer on another side in the stacking direction, the wiring layers being interposed between the semiconductor layers, each including an insulating film and a connection pad provided in the insulating film, and being electrically coupled to each other with surfaces of the connection pads bonded together,
in which the at least two semiconductor layers include a semiconductor layer with a photoelectric conversion region on a light incident surface side, and
a linear expansion coefficient of a material of a third portion which is a portion of the insulating film adjacent to a side surface of the connection pad is smaller than a linear expansion coefficient of a material of a fourth portion which is a portion of the insulating film adjacent to a bottom surface of the connection pad.
   (13)

The photodetector according to (12), in which the material of the third portion includes a glass ceramic with a linear expansion coefficient adjusted by an additive.

(14)

The photodetector according to (12), in which the linear expansion coefficient of the material of the third portion is a negative value.

(15)

The photodetector according to (14), in which the material of the third portion includes at least one of cubic zirconium tungstate, a Cu—Zn—V—O-based oxide, zirconium phosphate, zirconium phosphate tungstate, and a filler including a glass with a negative linear expansion coefficient.

(16)

The photodetector according to any one of (12) to (15), in which, between the third portion and the fourth portion, at least one of a silicon oxide film, a silicon nitride film, a silicon carbonitride film, a carbon-containing silicon oxide film, a silicon carbide film, an aluminum oxide film, and a tantalum oxide film is provided.

(17)

An electronic apparatus including:
a photodetector; and
an optical system configured to form an image of image light from an object on the photodetector,
the photodetector including
   at least two semiconductor layers, and
   a wiring layer on one side in a stacking direction and a wiring layer on another side in the stacking direction, the wiring layers being interposed between the semiconductor layers, each including an insulating film and a connection pad provided in the insulating film, and being electrically coupled to each other with surfaces of the connection pads bonded together,
in which the at least two semiconductor layers include a semiconductor layer with a photoelectric conversion region on a light incident surface side,
the insulating film includes a first insulating film and a second insulating film that includes a material with a higher rigidity than a material of the first insulating film and penetrates the first insulating film in the stacking direction, and
the second insulating film is provided between the connection pad and at least one of the semiconductor layers.
   (18)

An electronic apparatus including:
a photodetector; and
an optical system configured to form an image of image light from an object on the photodetector,
the photodetector including
   at least two semiconductor layers, and
   a wiring layer on one side in a stacking direction and a wiring layer on another side in the stacking direction, the wiring layers being interposed between the semiconductor layers, each including an insulating film and a connection pad provided in the insulating film, and being electrically coupled to each other with surfaces of the connection pads bonded together,
in which the at least two semiconductor layers include a semiconductor layer with a photoelectric conversion region on a light incident surface side, and
at least one of the connection pads has a first portion including a first metal and forming the surface of the at least one of the connection pads, and a second portion provided between the first portion and the insulating film and including a second metal that is more easily plastically deformed than the first metal.
   (19)

An electronic apparatus including:
a photodetector; and
an optical system configured to form an image of image light from an object on the photodetector,
the photodetector including
   at least two semiconductor layers, and
   a wiring layer on one side in a stacking direction and a wiring layer on another side in the stacking direction, the wiring layers being interposed between the semiconductor layers, each including an insulating film and a connection pad provided in the insulating film, and being electrically coupled to each other with surfaces of the connection pads bonded together,
in which the at least two semiconductor layers include a semiconductor layer with a photoelectric conversion region on a light incident surface side, and
a linear expansion coefficient of a material of a third portion which is a portion of the insulating film adjacent to a side surface of the connection pad is smaller than a linear expansion coefficient of a material of a fourth portion which is a portion of the insulating film adjacent to a bottom surface of the connection pad.

The scope of the present technology is not limited to the illustrative embodiments depicted in the drawings and described above and includes all embodiments that provide effects equivalent to the object of the present technology. Moreover, the scope of the present technology is not limited to the combinations of features of the invention defined by the claims and may be defined by all desired combinations of specific features among all the features disclosed.

### REFERENCE SIGNS LIST

1: Photodetector
2: Semiconductor chip
2A: Pixel region
2B: Peripheral region
3: Pixel
4: Vertical drive circuit
5: Column signal processing circuit
6: Horizontal drive circuit
7: Output circuit
8: Control circuit
10: Pixel drive line
11: Vertical signal line
12: Horizontal signal line
13: Logic circuit
14: Bonding pad
15: Readout circuit
20: First semiconductor layer
20a: Photoelectric conversion region
30: First wiring layer
31, 31A, 31B: Insulating film
32: Wiring line
33: First connection pad
35: First insulating film
36: Second insulating film
40: Second wiring layer
41, 41A, 41B: Insulating film
42: Wiring line
43: Second connection pad
43a: Bottom surface
45: First insulating film
46: Second insulating film
50: Second semiconductor layer
60: Third wiring layer
61, 61A, 61B: Insulating film
62: Wiring line
63: Third connection pad
63a: Bottom surface
63S: Surface
65: First insulating film
66: Second insulating film
70: Fourth wiring layer
71, 71A, 71B: Insulating film
72: Wiring line
73: Fourth connection pad
73S: Surface
75: First insulating film
76: Second insulating film
80: Third semiconductor layer
100: Electronic apparatus
101: Solid-state image pickup device
102: Optical system (optical lens)
103: Shutter device
104: Drive circuit
105: Signal processing circuit
a: First portion
A, A1, A2, B: Connection pad
Connection pad
b: Second portion
b1: Sidewall portion
B1: Side surface
B2: Bottom surface
c: Seed layer
d: Insulating film
da, da31, da41, da61, da71: Insulating film
db, db31, db41, db61, db71: Insulating film
f: Barrier metal layer
g: Contact layer
P, P1, Pa, Pb: Pillar

1. A photodetector comprising:
at least two semiconductor layers; and
a wiring layer on one side in a stacking direction and a wiring layer on another side in the stacking direction, the wiring layers being interposed between the semiconductor layers, each including an insulating film and a connection pad provided in the insulating film, and being electrically coupled to each other with surfaces of the connection pads bonded together,
wherein the at least two semiconductor layers include a semiconductor layer with a photoelectric conversion region on a light incident surface side,
the insulating film includes a first insulating film and a second insulating film that includes a material with a higher rigidity than a material of the first insulating film and penetrates the first insulating film in the stacking direction, and
the second insulating film is provided between the connection pad and at least one of the semiconductor layers.

2. The photodetector according to claim 1,
wherein the second insulating film has a pillar-shaped portion that extends along the stacking direction, and
one end of the pillar-shaped portion in the stacking direction is in contact with the connection pad, and another end thereof is in contact with one of the semiconductor layers.

3. The photodetector according to claim 2, wherein the pillar-shaped portion is provided at a position that does not overlap with a wiring line formed in the insulating film in the stacking direction.

4. The photodetector according to claim 3, wherein a plurality of the pillar-shaped portions is provided for one of the connection pads.

5. The photodetector according to claim 1, wherein a dielectric constant of the material of the first insulating film is lower than a dielectric constant of the material of the second insulating film.

6. The photodetector according to claim 1, wherein the material of the second insulating film includes silicon oxide, silicon nitride, or silicon oxide and silicon nitride.

7. A photodetector comprising:
at least two semiconductor layers; and
a wiring layer on one side in a stacking direction and a wiring layer on another side in the stacking direction, the wiring layers being interposed between the semiconductor layers, each including an insulating film and a connection pad provided in the insulating film, and being electrically coupled to each other with surfaces of the connection pads bonded together,
wherein the at least two semiconductor layers include a semiconductor layer with a photoelectric conversion region on a light incident surface side, and
at least one of the connection pads has a first portion including a first metal and forming the surface of the at least one of the connection pads, and a second portion provided between the first portion and the insulating film and including a second metal that is more easily plastically deformed than the first metal.

8. The photodetector according to claim 7, wherein the second portion is provided between at least a side surface of the first portion and the insulating film.

9. The photodetector according to claim 7, wherein a melting point of the second metal is lower than a melting point of the first metal.

10. The photodetector according to claim 7, wherein the second portion includes a seed layer configured to function as a base for stacking the first metal or a barrier metal layer configured to prevent the first metal from being diffused into the insulating film.

11. The photodetector according to claim 7,
wherein the first metal includes copper, and
the second metal includes aluminum, an aluminum-copper alloy, an aluminum-silicon alloy, cadmium, tin, tantalum, lead, a lead-copper alloy, antimony, ytterbium, calcium, silver, germanium, strontium, or cerium.

12. A photodetector comprising:
at least two semiconductor layers; and
a wiring layer on one side in a stacking direction and a wiring layer on another side in the stacking direction, the wiring layers being interposed between the semiconductor layers, each including an insulating film and a connection pad provided in the insulating film, and being electrically coupled to each other with surfaces of the connection pads bonded together,
wherein the at least two semiconductor layers include a semiconductor layer with a photoelectric conversion region on a light incident surface side, and
a linear expansion coefficient of a material of a third portion which is a portion of the insulating film adjacent to a side surface of the connection pad is smaller than a linear expansion coefficient of a material of a fourth portion which is a portion of the insulating film adjacent to a bottom surface of the connection pad.

13. The photodetector according to claim 12, wherein the material of the third portion includes a glass ceramic with a linear expansion coefficient adjusted by an additive.

14. The photodetector according to claim 12, wherein the linear expansion coefficient of the material of the third portion is a negative value.

15. The photodetector according to claim 14, wherein the material of the third portion includes at least one of cubic zirconium tungstate, a Cu—Zn—V—O-based oxide, zirconium phosphate, zirconium phosphate tungstate, and a filler including a glass with a negative linear expansion coefficient.

16. The photodetector according to claim 12, wherein, between the third portion and the fourth portion, at least one of a silicon oxide film, a silicon nitride film, a silicon carbonitride film, a carbon-containing silicon oxide film, a silicon carbide film, an aluminum oxide film, and a tantalum oxide film is provided.

17. An electronic apparatus comprising:
a photodetector; and
an optical system configured to form an image of image light from an object on the photodetector,
the photodetector including
at least two semiconductor layers, and
a wiring layer on one side in a stacking direction and a wiring layer on another side in the stacking direction, the wiring layers being interposed between the semiconductor layers, each including an insulating film and a connection pad provided in the insulating film, and being electrically coupled to each other with surfaces of the connection pads bonded together,
wherein the at least two semiconductor layers include a semiconductor layer with a photoelectric conversion region on a light incident surface side,
the insulating film includes a first insulating film and a second insulating film that includes a material with a higher rigidity than a material of the first insulating film and penetrates the first insulating film in the stacking direction, and
the second insulating film is provided between the connection pad and at least one of the semiconductor layers.
